(19) United States
(12) Patent Application Publication
(10) Pub. No.: US 2025/0126788 A1
(43) Pub. Date: Apr. 17, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Donghoon Kwon, Suwon-si (KR); Yong Sik Chung, Suwon-si (KR)

(21) Appl. No.: 18/653,158

(22) Filed: May 2, 2024

(30) Foreign Application Priority Data
Oct. 13, 2023 (KR) 10-2023-0136973

(51) Int. Cl. H10B 43/27; H01L 23/522

(52) U.S. Cl. CPC H10B 43/27; H01L 23/5226

(57) ABSTRACT

A semiconductor device includes a substrate including a circuit region and a cell region. The cell region includes a gate stacking structure, a channel structure that extends into the gate stacking structure and is on the cell array region, a through-gate contact portion that extends into the gate stacking structure and is electrically connected to a connection gate electrode, and an upper gate contact portion that is electrically connected to an upper gate electrode, where the upper gate electrode is separated from the substrate by a first distance, the connection gate electrode is separated from the substrate by a second distance, and where the second distance is less than the first distance, and where the upper gate contact portion includes a first portion and a second portion, and a boundary between the first portion and the second portion has a step shape.

### CROSS-REFERENCE TO RELATED APPLICATION

This application claims priority to and the benefit of Korean Patent Application No. 10-2023-0136973 filed in the Korean Intellectual Property Office on Oct. 13, 2023, the entire contents of which is incorporated herein by reference.

### TECHNICAL FIELD

The present disclosure relates to a semiconductor device and an electronic system including the same.

### BACKGROUND

A semiconductor is a material belonging to an intermediate region between a conductor and an insulator, and refers to a material that conducts electricity under a predetermined condition. Various semiconductor devices can be manufactured by using such a semiconductor material, and for example, a memory device and the like can be manufactured. Memory devices may be classified into volatile memory devices and non-volatile memory devices. In the case of a non-volatile memory device, contents may not be deleted even if power is cut off, and may be used in various electronic devices, such as mobile phones, digital cameras, and PCs.

In accordance with recent trend of increasing storage capacity, a degree of integration of non-volatile memory devices may be desired to be improved. The degree of integration of memory devices two-dimensionally arranged on a plane may be limited. Accordingly, a vertical non-volatile memory device arranged in three dimensions has been proposed.

### SUMMARY

The present disclosure provides a semiconductor device having enhanced reliability productivity and an electronic system including the semiconductor device provide.

A semiconductor device may include a substrate including a circuit region and a cell region, where the circuit region includes a peripheral circuit structure on the substrate, where the cell region is on the circuit region and includes a cell array region and a connecting region, and where the cell region includes: a gate stacking structure including a plurality of interlayer insulation layers and a plurality of gate electrodes that are alternately stacked on the substrate, a channel structure that extends into the gate stacking structure and is on the cell array region, a through-gate contact portion that extends into the gate stacking structure and is on the connecting region, where the through-gate contact portion is electrically connected to a connection gate electrode among the plurality of gate electrodes, where the plurality of gate electrodes extend into an insulation pattern, and an upper gate contact portion that is electrically connected to an upper gate electrode among the plurality of gate electrodes, where the upper gate electrode is separated from the substrate by a first distance in a vertical direction that is perpendicular to the substrate, where the connection gate electrode is separated from the substrate by a second distance in the vertical direction, and where the second distance is less than the first distance, and where the upper gate contact portion includes a first portion and a second portion, and where a boundary between the first portion and the second portion has a step shape.

A semiconductor device may include a substrate including a circuit region and a cell region, where the circuit region includes a peripheral circuit structure positioned on the substrate, where the cell region is on the circuit region, where the cell region includes: a gate stacking structure including a plurality of interlayer insulation layers and a plurality of gate electrodes that are alternately stacked on the substrate, a first channel structure that extends into the gate stacking structure, a selection gate electrode on the gate stacking structure, a second channel structure that extends into the selection gate electrode and is electrically connected to the first channel structure, a through-gate contact portion that extends into the selection gate electrode and the gate stacking structure and is electrically connected to a connection gate electrode among the plurality of gate electrodes, where the plurality of gate electrodes extend into an insulation pattern, and an upper gate contact portion that extends into the selection gate electrode and is electrically connected to an upper gate electrode among the plurality of gate electrodes, where the upper gate electrode is separated from the substrate by a first distance in a vertical direction that is perpendicular to the substrate, where the connection gate electrode is separated from the substrate by a second distance in the vertical direction, and where the second distance is less than the first distance, where the upper gate contact portion includes: a first portion that is separated from the substrate by a third distance in the vertical direction, where the selection gate electrode is separated from the substrate by a fourth distance in the vertical direction, and where the third distance is less than the fourth distance, and a second portion that extends into the selection gate electrode and is on the first portion, and where a width of an upper surface of the first portion of the upper gate contact portion and a width of a bottom surface of the second portion of the upper gate contact portion are different.

An electronic system may include a main substrate, a semiconductor device on the main substrate, and a controller that is electrically connected to the semiconductor device and is on the main substrate, where the semiconductor device includes a circuit region including a peripheral circuit structure on a substrate and a cell region on the circuit region, where the cell region includes: a gate stacking structure including a plurality of interlayer insulation layers and a plurality of gate electrodes that are alternately stacked on the substrate, a first channel structure that extends into the gate stacking structure, a selection gate electrode on the gate stacking structure, a second channel structure that extends into the selection gate electrode and is electrically connected to the first channel structure, a through-gate contact portion that extends into the selection gate electrode and the gate stacking structure, is electrically connected to a connection gate electrode among the plurality of gate electrodes that extend into an insulation pattern, and is insulated from one or more second gate electrodes among the plurality of electrodes, and an upper gate contact portion that extends into the selection gate electrode and is electrically connected to an upper gate electrode among the plurality of gate electrodes, where the upper gate electrode is separated from the substrate by a first distance in a vertical direction that is perpendicular to the substrate, where the connection gate electrode is separated from the substrate by a second distance in the vertical direction, and where the second distance is less than the first distance, where the upper gate contact portion includes: a first portion that is separated from the substrate by a third distance in the vertical direction, where the selection gate electrode is separated from the substrate by a fourth distance in the vertical direction, and where the third distance is less than the fourth distance, and a second portion that extends into the selection gate electrode and is on the first portion, where a width of an upper surface of the first portion of the upper gate contact portion and a width of a bottom surface of the second portion of the upper gate contact portion are different, and where a length of the first portion of the upper gate contact portion in the vertical direction is different from a length of the second portion of the upper gate contact portion in the vertical direction.

According to some embodiments, in the process step of forming a through-gate contact portion penetrating or extending into a gate stacking structure or the like, the gate contact portion connected to the upper gate electrode may be formed together such that the process step for forming the gate contact portion may be omitted. Accordingly, the process may be easily controlled and simplified, thereby improving productivity of the semiconductor device.

### BRIEF DESCRIPTION OF THE DRAWINGS

FIG. 1 is a cross-sectional view showing a semiconductor device according to some embodiments.

FIG. 2 is a cross-sectional view showing a channel structure included in the semiconductor device shown in FIG. 1.

FIG. 3 is a partial enlarged view of a region R1 of FIG. 1.

FIG. 4 is a partial enlarged view of a region R2 of FIG. 1.

FIG. 5 is a partial enlarged view of a region R3 of FIG. 1.

FIGS. 6, 7, 8, and 9 are partial enlarged views showing cross-sections of a semiconductor device according to some embodiments.

FIG. 10 is a cross-sectional view schematically showing a semiconductor device according to some embodiments.

FIGS. 11, 12, 13, 14, 15, and 16 are cross-sectional views describing a manufacturing method of a semiconductor device according to some embodiments.

FIGS. 17, 18, 19, 20, 21, 22, 23, 24, and 25 are cross-sectional views describing a manufacturing method of a semiconductor device according to some embodiments.

FIG. 26 is a drawing schematically showing an electronic system including a semiconductor device according to some embodiments.

FIG. 27 is a perspective view schematically showing an electronic system including a semiconductor device according to some embodiments.

FIGS. 28 and 29 are cross-sectional views schematically showing a semiconductor package according to some embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

To clearly describe the present disclosure, parts that are irrelevant to the description are omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

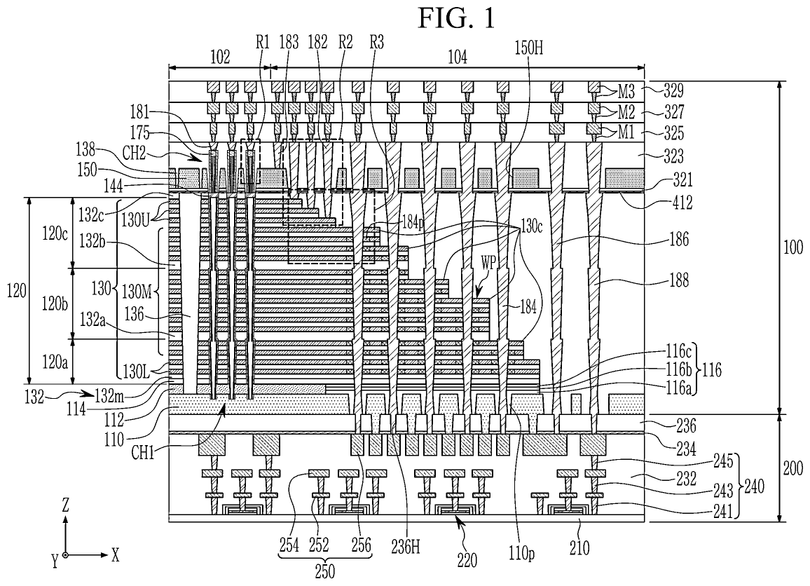

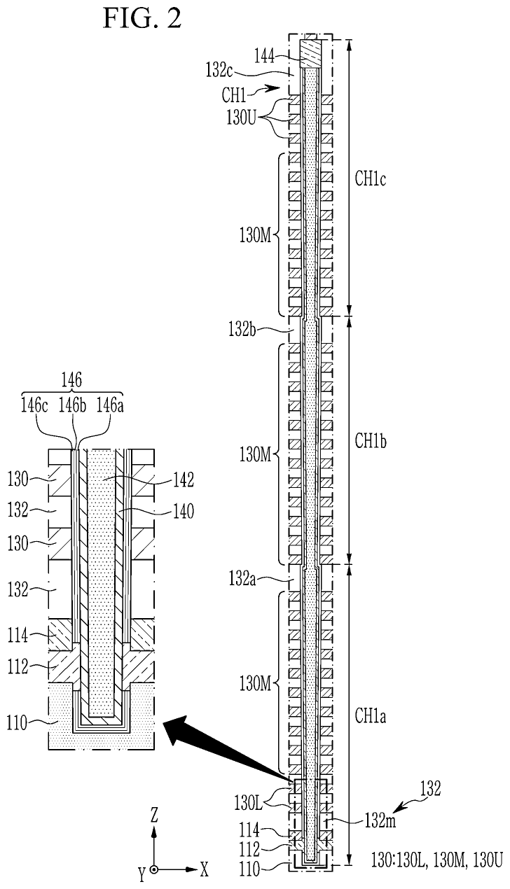

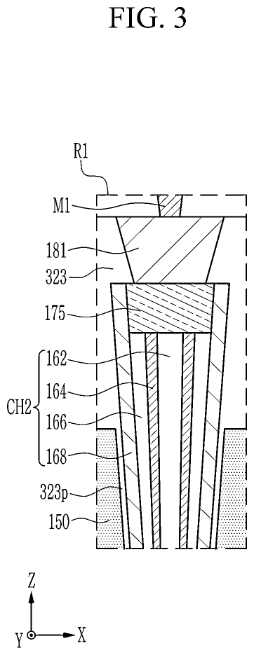

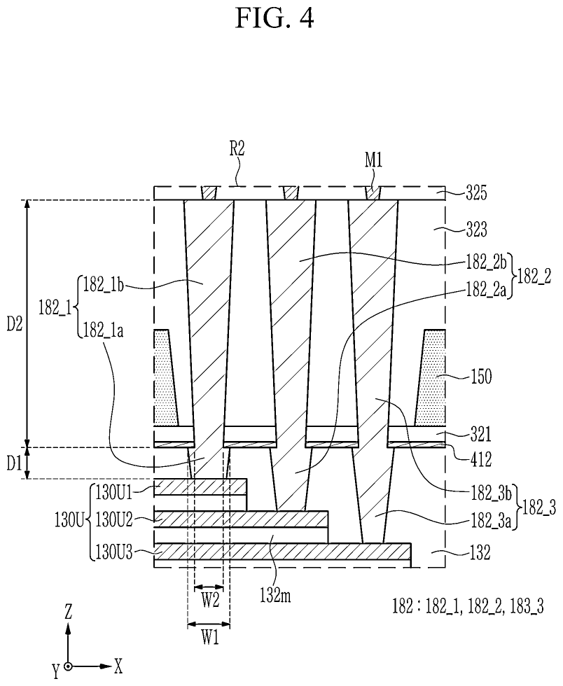

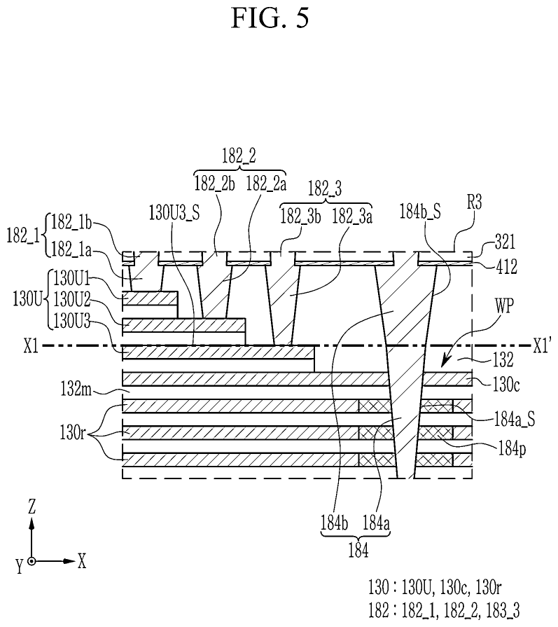

FIG. 1 is a cross-sectional view showing a semiconductor device according to an embodiment. FIG. 2 is a cross-sectional view showing a channel structure included in the semiconductor device shown in FIG. 1. FIG. 3 is a partial enlarged view of a region R1 of FIG. 1. FIG. 4 is a partial enlarged view of a region R2 of FIG. 1. FIG. 5 is a partial enlarged view of a region R3 of FIG. 1.

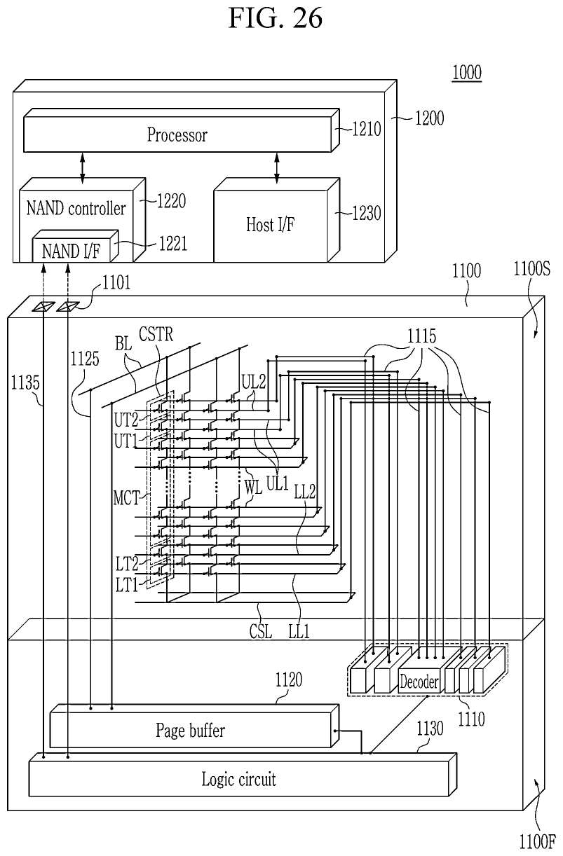

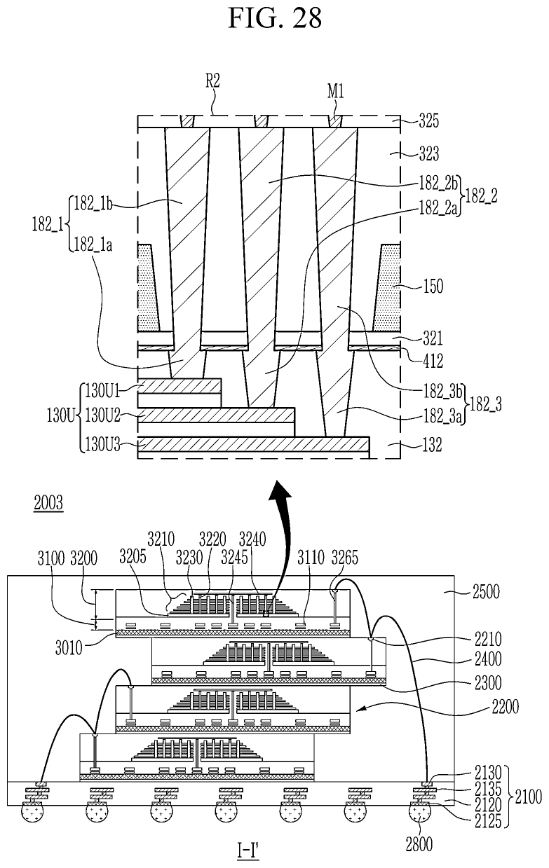

Referring to FIG. 1 to FIG. 5, a semiconductor device according to some embodiments may include a cell region 100 including a memory cell structure and a circuit region 200 including a peripheral circuit structure for controlling an operation of the memory cell structure. For example, the circuit region 200 and the cell region 100 may be portions that correspond to a first structure 1100F and a second structure 1100S of a semiconductor device 1100 included in an electronic system 1000 shown in FIG. 26, respectively. As another example, the circuit region 200 and the cell region 100 may be portions that correspond to a first structure 3100 and a second structure 3200 of a semiconductor chip 2200 shown in FIG. 28, respectively.

In some embodiments, the cell region 100 may be positioned on the circuit region 200. Accordingly, since it may not be necessary to secure the area corresponding to the circuit area 200 separately from the cell area 100, the area of the semiconductor device may be reduced. However, the arrangement relationship of the circuit region 200 and the cell region 100 is not limited thereto, and may be changed in various ways. For example, the circuit region 200 may be positioned next to the cell region 100.

The circuit region 200 may include a first substrate 210, a circuit element 220, a lower conductive via 240, a lower wire 250, and circuit insulation layers 232, 234, and 236.

The first substrate 210 may be a semiconductor substrate including a semiconductor material. For example, the first substrate 210 may be a semiconductor substrate made of a semiconductor material, and may be a semiconductor substrate in which a semiconductor layer is formed on a base substrate. The first substrate 210 may include silicon, epitaxial silicon, germanium, silicon-germanium, silicon-on-insulator (SOI), or germanium-on-insulator (GOI), or the like.

The circuit element 220 positioned on the first substrate 210 may include various circuit elements for controlling the operation of a memory cell structure provided in the cell region 100. For example, the circuit element 220 may form peripheral circuit structures, such as a decoder circuit (refer to the semiconductor device 1100 of FIG. 26), a page buffer (refer to the semiconductor device 1100 of FIG. 26), a logic circuit (refer to the semiconductor device 1100 of FIG. 26), or the like.

The circuit element 220 may include, for example, a transistor, but is not limited thereto. For example, the circuit element 220 may include not only an active element such as a transistor, but also a passive element, such as a capacitor, a resistor, and an inductor.

The lower wire 250 positioned on the first substrate 210 may be electrically connected to the circuit element 220. The lower wire 250 may include a plurality of first to third lower wire layers 252, 254, and 256 connected to form a desired path by a plurality of lower conductive vias 241, 243, and 245 spaced apart and extending into a first circuit insulation layer 232.

The first circuit insulation layer 232 may be a structure in which a plurality of insulation layers insulating between the first to third lower wire layers 252, 254, and 256 are stacked, and may have via holes with the lower conductive vias 241, 243, and 245 therein.

The lower conductive via 240 and the lower wire 250 may include a conductive material, and the first circuit insulation layer 232 may include an insulating material. For example, the lower conductive via 240 and the lower wire 250 may include a metal, such as tungsten, and the first circuit insulation layer 232 may include silicon oxide or the like.

In some embodiments, it is illustrated that the lower wire 250 includes an three wire layers 252, 254, and 256, and the lower conductive via 240 includes three vias 241, 243, and 245, but the present disclosure is not limited thereto, and the number of these wire layers and vias may be two or less or four or more.

A second circuit insulation layer 234 may be positioned on the first circuit insulation layer 232. In the process step for forming the cell region 100 to be described later, the second circuit insulation layer 234 may decrease or inhibit hydrogen from being impregnated and diffused into the circuit region 200 positioned below the cell region 100. That is, the second circuit insulation layer 234 may serve as a hydrogen blocking layer. The second circuit insulation layer 234 may include, for example, silicon nitride or the like.

A third circuit insulation layer 236 may be positioned on the second circuit insulation layer 234. The third circuit insulation layer 236 may include a contact hole 236H for connecting a second substrate 110 or contact portions 184, 186, and 188 of the cell region 100 to be described later and a third lower wire layer 256 of the circuit region 200. The third circuit insulation layer 236 may include, for example, silicon oxide or the like.

The cell region 100 may include a cell array region 102 and a connecting region 104.

In the cell array region 102, a gate stacking structure 120 channel structures CH1 and CH2 may be positioned on the second substrate 110. In the cell array region 102 and/or the connecting region 104, a structure for connecting the gate stacking structure 120 and/or channel structures CH1 and CH2 positioned in the cell array region 102 to the circuit region 200 or an external circuit may be positioned.

In more detail, the cell region 100 may include the second substrate 110, horizontal conductive layers 112 and 114, a horizontal insulation layer 116, the gate stacking structure 120, a first channel structure CH1, first and second contact electrodes 181 and 183, an upper gate contact portion 182, a through-gate contact portion 184, a source contact portion 186, a through-contact portion 188, a separation structure 136, a selection gate electrode 150, a second channel structure CH2, an upper separation structure 138, upper insulation layers 412, 321, 323, 325, 327, and 329, and upper wire structures M1, M2, and M3.

In some embodiments, the second substrate 110 may include a semiconductor material. For example, the second substrate 110 may be a semiconductor substrate made of a semiconductor material, and may be a semiconductor substrate in which a semiconductor layer is formed on a base substrate. For example, the second substrate 110 may include polysilicon doped with impurities. The second substrate 110 may function as a common source line. The second substrate 110 may function as a source region that supplies current to memory cells positioned on the second substrate 110. The second substrate 110 may be formed in a plate shape. That is, the second substrate 110 may be formed as a plate common source line.

As another example, the second substrate 110 may include silicon, germanium, silicon-germanium, silicon-on-insulator, or germanium-on-insulator or the like. Here, the semiconductor material included in the second substrate 110 may be doped with P-type or N-type impurities, and for example, N-type impurities (e.g., phosphorus (P), arsenic (As), or the like) may be doped. However, the conductivity type, material, or the like of the impurities doped in the semiconductor material are not limited thereto, and may be changed in various ways.

The second substrate 110 may be connected to the third lower wire layer 256 of the circuit region 200. That is, a portion of the second substrate 110 may be directly connected to the third lower wire layer 256 of the circuit region 200 through the contact hole 236H included in the third circuit insulation layer 236.

In the second substrate 110, a substrate insulation pattern 110p may be positioned in a region penetrated by the contact portions 184, 186, and 188 to be described later. That is, since the substrate insulation pattern 110p is positioned between the second substrate 110 and the contact portions 184, 186, and 188 extending from the cell region 100 toward the circuit region 200 and penetrating or extending into the second substrate 110, the second substrate 110, and the contact portions 184, 186, and 188 may be separated and insulated.

In the cell array region 102, the gate stacking structure 120 including a cell insulation layer 132 and a gate electrode 130 alternately stacked on first surface (e.g., front surface or upper surface) of the second substrate 110, and the first channel structure CH1 penetrating or extending into the gate stacking structure 120 and extending in a direction crossing the second substrate 110 may be positioned.

In the cell array region 102, the horizontal conductive layers 112 and 114 may be positioned between the second substrate 110 and the gate stacking structure 120. The horizontal conductive layers 112 and 114 may serve to electrically connect between the first channel structure CH1 and the second substrate 110. For example, the horizontal conductive layers 112 and 114 may include a first horizontal conductive layer 112 positioned on a first surface of the second substrate 110, and may further include a second horizontal conductive layer 114 positioned on the first horizontal conductive layer 112. That is, the first horizontal conductive layer 112 may be positioned between the second substrate 110 and the second horizontal conductive layer 114.

In a partial region of the connecting region 104 that is between the second substrate 110 and the gate stacking structure 120, the first horizontal conductive layer 112 may not be positioned, but the horizontal insulation layer 116 may be positioned. In a manufacturing process, a portion of the horizontal insulation layer 116 may be replaced with the first horizontal conductive layer 112, and in this case, another portion of the horizontal insulation layer 116 positioned in the connecting region 104 may remain in the connecting region 104.

As shown in FIG. 1, the horizontal insulation layer 116 may be formed in multiple layers including a plurality of insulation layers 116a, 116b, and 116c. However, it is not limited thereto, and in some embodiments, the horizontal insulation layer 116 may be formed in a single layer, or an oxide layer may be additionally positioned on upper and/or lower portions of the horizontal insulation layer 116.

The first horizontal conductive layer 112 may function as a portion of a common source line of a semiconductor device. For example, the first horizontal conductive layer 112 may function as a common source line together with the second substrate 110. As shown in FIG. 2, the first channel structure CH1 may penetrate or extend into the horizontal conductive layers 112 and 114 to reach the second substrate 110, and a first gate dielectric layer 146 is removed in a portion where the first horizontal conductive layer 112 is positioned such that the first horizontal conductive layer 112 may be directly connected to the first channel layer 140 at a circumference of a first channel layer 140. Therefore, the first horizontal conductive layer 112 may electrically connect between the second substrate 110 and the first channel layer 140.

First and second horizontal conductive layers 112 and 114 may include a semiconductor material (e.g., polysilicon). For example, the first horizontal conductive layer 112 may include polysilicon doped with impurities, and the second horizontal conductive layer 114 may include polysilicon doped with impurities, or may be layer including impurities diffused from the first horizontal conductive layer 112. However, the present disclosure is not limited thereto, and the second horizontal conductive layer 114 may include an insulating material. In addition, in some embodiments, the second horizontal conductive layer 114 may be omitted.

On the first and the second horizontal conductive layers 112 and 114 formed on the second substrate 110, for example, on the second substrate 110, the gate stacking structure 120 in which the cell insulation layer 132 and the gate electrode 130 are alternately stacked may be positioned.

In some embodiments, the gate stacking structure 120 may include a plurality of gate stacking structures 120a, 120b, and 120c sequentially stacked on the second substrate 110. Accordingly, the number of the stacked gate electrode 130 may be increased, and the number of memory cells may be increased in a stable structure. For example, the gate stacking structure 120 includes first to third gate stacking structures 120a, 120b, and 120c, thereby increasing data storage capacity while simplifying the structure. However, the number of the stacked gate stacking structure 120 is not limited thereto, and the gate stacking structure 120 may be configured as two, or four or more gate stacking structures.

In the gate stacking structure 120, the gate electrode 130 may include a lower gate electrode 130L, a memory cell gate electrode 130M, and an upper gate electrode 130U sequentially positioned from an upper surface of the second substrate 110.

The lower gate electrode 130L may be used as a gate electrode of a ground select transistor, the memory cell gate electrode 130M may form a memory cell, and the upper gate electrode 130U may be used as a gate electrode of an erase transistor used for an erase operation utilizing the gate induced drain leakage (GIDL) phenomenon.

The number of the memory cell gate electrode 130M may be determined depending on the data storage capacity of the semiconductor device. Depending on embodiments, the lower gate electrode 130L and the upper gate electrode 130U may be provided as a quantity of one or two or more, respectively, and may have a structure substantially the same as or different from the memory cell gate electrode 130M.

In addition, a portion of the gate electrode 130, for example, a portion of the upper gate electrode 130U may be a dummy gate electrode. As another example, in some embodiments, when the selection gate electrode 150 positioned on the gate stacking structure 120 is omitted, a portion of the upper gate electrode 130U may be used as a gate electrode of a string select transistor, and a remaining portion may be used as a gate electrode of an erase transistor used for an erase operation utilizing the gate induced drain leakage (GIDL) phenomenon.

The cell insulation layer 132 may include an interlayer insulation layer 132m positioned between neighboring two gate electrodes 130 or a lower portion of the gate electrode 130 within the first to third gate stacking structures 120a, 120b, and 120c, and gate upper insulation layers 132a, 132b, and 132c positioned in an upper portion of each of the first to third gate stacking structures 120a, 120b, and 120c.

For example, the gate upper insulation layers 132a, 132b, and 132c may include first to third gate upper insulation layers 132a, 132b, and 132c positioned in upper portions of the first to third gate stacking structures 120a, 120b, and 120c, respectively.

Here, first and second gate upper insulation layers 132a and 132b is an intermediate insulation layer positioned between the first gate stacking structure 120a and the second gate stacking structure 120b and between the second gate stacking structure 120b and the third gate stacking structure 120c, and a third gate upper insulation layer 132c is an uppermost insulation layer positioned in an uppermost portion of the gate stacking structure 120. The third gate upper insulation layer 132c may form a part or all of a cell region insulation layer positioned entirely in an upper portion of the cell region 100.

In some embodiments, thicknesses of a plurality of cell insulation layers 132 may not be all the same. For example, thicknesses of the gate upper insulation layers 132a, 132b, and 132c may be thicker than a thickness of the interlayer insulation layer 132m. However, the shape, structure, and arrangement of the cell insulating layer 132 are not limited thereto and may change in various ways.

For simplicity of illustration, in FIG. 1, in the connecting region 104, the cell insulation layer 132 is shown to have one layer without a boundary, but the present disclosure is not limited thereto, and in the connecting region 104, one or a plurality of insulation layers may have various stacking structures, and the present disclosure is not limited thereto.

The gate electrode 130 may include various conductive materials. For example, the gate electrode 130 may include a metal material such as tungsten (W), copper (Cu), aluminum (Al), or the like, polysilicon, metal nitride (e.g., titanium nitride (TiN), tantalum nitride (TaN), or the like), or a combination thereof. In one variation, outside of the gate electrode 130, an insulation layer made of an insulating material may be positioned, or a portion of the first gate dielectric layer 146 may be positioned.

The cell insulation layer 132 may include various insulating materials. For example, the cell insulation layer 132 may include silicon oxide, silicon nitride, silicon nitride oxide, a low dielectric constant material having smaller dielectric constant than silicon oxide, or a combination thereof.

In the cell array region 102, the first channel structure CH1 may penetrate or extend into the gate stacking structure 120 and extend in direction (e.g., a third direction Z that is a direction perpendicular to the second substrate 110) crossing or intersecting the second substrate 110.

In more detail, the first channel structure CH1 may include the first gate dielectric layer 146 that is positioned on the first channel layer 140 at the first channel layer 140 and is between the gate electrode 130 and the first channel layer 140. The first channel structure CH1 may further include a first core insulation layer 142 positioned in an interior of the first channel layer 140, and may further include a first channel pad 144 disposed on the first channel layer 140 and/or the first gate dielectric layer 146.

Each first channel structure CH1 may form one memory cell string, and in a plan view, a plurality of first channel structures CH1 may be arranged in rows and columns to be spaced apart from each other. For example, in a plan view, the plurality of first channel structures CH1 may be arranged in various forms, such as a lattice form, a zigzag form, or the like. The first channel structure CH1 may have a pillar shape. For example, the first channel structure CH1 may have, in cross-section, an inclined side surface such that the width narrows as it becomes closer to the second substrate 110 according to the aspect ratio. However, the present disclosure is not limited thereto, and the arrangement, structure, shape, and the like of the first channel structure CH1 may be changed in various ways.

The first core insulation layer 142 may be positioned in a central portion of the first channel structure CH1, and the first channel layer 140 may at least partially surround a side surface of the first core insulation layer 142. For example, the first core insulation layer 142 may have a pillar shape (e.g., circular cylinder shape or polygonal pillar shape), and the first channel layer 140 may have a planar shape of an annular shape or the like. However, the present disclosure is not limited thereto, and the first core insulation layer 142 may be omitted, and the first channel layer 140 may have a pillar shape (e.g., circular cylinder shape or polygonal pillar shape).

The first channel layer 140 may include a semiconductor material, for example, polysilicon. The first core insulation layer 142 may include various insulating materials. For example, the first core insulation layer 142 may include silicon oxide, silicon nitride, silicon nitride oxide, or a combination thereof. However, the material of the first channel layer 140 and the first core insulation layer 142 is not limited thereto, and may be changed in various ways.

The first gate dielectric layer 146 positioned between the gate electrode 130 and the first channel layer 140 may include a tunneling layer 146a, a charge storage layer 146b, and a blocking layer 146c sequentially stacked on the first channel layer 140.

Herein, the tunneling layer 146a is a layer through which charges are tunneled according to a voltage applied to the gate electrode 130, and may include an insulating material capable of tunneling charges. The tunneling layer 146a may include a material such as silicon oxide and silicon nitride oxide. For example, the tunneling layer 146a may be formed by stacking a layer including silicon oxide and a layer including silicon nitride.

The charge storage layer 154 disposed between the tunneling layer 152 and the blocking layer 156 may be used as a data storage region. For example, the charge storage layer 146b may include silicon nitride capable of trapping charges. When the charge storage layer 146b is made of silicon nitride, it may have excellent retention and may be advantageous for integration compared to being made of polysilicon. However, the material of the charge storage layer 146b is not limited thereto, and may be changed in various ways.

The blocking layer 146c may be positioned between the charge storage layer 146b and the gate electrode 130. The blocking layer 146c may include an insulating material that may prevent charges from undesirably flowing into the gate electrode 130. For example, the blocking layer 146c may include silicon oxide, silicon nitride, silicon nitride oxide, a high dielectric constant material or a combination thereof.

Here, high dielectric constant material means a dielectric material having a higher dielectric constant than silicon oxide. For example, high dielectric constant material may include aluminum oxide (Al₂O₃), tantalum oxide (Ta₂O₃), titanium oxide TiO₂, yttrium oxide Y₂O₃, zirconium oxide ZrO₂, zirconium silicon oxide (ZrSiₓO_{y}), hafnium oxide HfO₂, hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), praseodymium oxide (Pr₂O₃), or a combination thereof.

The first channel pad 144 may be positioned on the first channel layer 140 and/or the first gate dielectric layer 146. The first channel pad 144 may cover or overlap an upper surface of the first core insulation layer 142, and may be positioned to be electrically connected to the first channel layer 140. In FIG. 1 and FIG. 2, the first channel pad 144 is shown to cover or overlap an upper surface of the first gate dielectric layer 146, but the present disclosure is not limited thereto. For example, the first channel pad 144 may not cover or overlap the upper surface of the first gate dielectric layer 146. That is, a side surface of the first channel pad 144 may be at least partially surrounded by the first gate dielectric layer 146. The side surface of the first channel pad 144 may contact the tunneling layer 146a. The first channel pad 144 may include a conductive material, for example, polysilicon doped with impurities. However, material of the first channel pad 144 is not limited thereto, and may be changed in various ways.

As described above, when the gate stacking structures 120 include the first gate stacking structure 120a, the second gate stacking structure 120b, and the third gate stacking structure 120c, the first channel structure CH1 may include a plurality of sub-channel structures CH1a, CH1b, and CH1c that penetrate or extend into the plurality of gate stacking structures 120a, 120b, and 120c, respectively. For example, when the plurality of gate stacking structures 120 include the first gate stacking structure 120a, the second gate stacking structure 120b, and the third gate stacking structure 120c, the first channel structure CH1 may include a first sub-channel structure CH1a that penetrates or extends into the first gate stacking structure 120a, a second sub-channel structure CH1b that penetrates or extends into the second gate stacking structure 120b, and a third sub-channel structure CH1c that penetrates or extends into the third gate stacking structure 120c.

First to third sub-channel structures CH1a, CH1b, and CH1c may be connected to each other. Each of the first to third sub-channel structures CH1a, CH1b, and CH1c may have, in a cross-sectional view, an inclined side surface such that the width narrows as it becomes closer to the second substrate 110 according to the aspect ratio. As shown in FIG. 2, a portion where the first sub-channel structure CH1a and the second sub-channel structure CH1b are connected and a portion where the second sub-channel structure CH1b and the third sub-channel structure CH1c are connected may include a bent portion due to a width difference. However, the connection form of the first to third sub-channel structures CH1a, CH1b, and CH1c is not limited thereto, and may be changed in various ways. For example, in some embodiments, the first to third sub-channel structures CH1a, CH1b, and CH1c may have an inclined side surface that is continuous without a bent portion.

In FIG. 2, the first gate dielectric layer 146, the first channel layer 140 and the first core insulation layer 142 of the first to third sub-channel structures CH1a, CH1b, and CH1c are shown to have an integral structure in which they are formed by extending. After forming first to third sub-channel holes for the first to third sub-channel structures CH1a, CH1b, and CH1c, the above-described structure may be formed by forming the first gate dielectric layer 146, the first channel layer 140 and the first core insulation layer 142 throughout the first to third sub-channel holes. However, the present disclosure is not limited thereto. For example, the first gate dielectric layer 146, the first channel layer 140 and the first core insulation layer 142 of the first to third sub-channel structures CH1a, CH1b, and CH1c may be formed separately from each other to be electrically connected. That is, the first gate dielectric layer 146, the first channel layer 140 and the first core insulation layer 142 may be formed in the first sub-channel hole after forming the first sub-channel hole for the first sub-channel structure CH1a, the first gate dielectric layer 146, the first channel layer 140 and the first core insulation layer 142 may be formed in the second sub-channel hole after forming the second sub-channel hole for the second sub-channel structure CH1b, and the first gate dielectric layer 146, the first channel layer 140 and the first core insulation layer 142 may be formed in the third sub-channel hole after forming the third sub-channel hole for the third sub-channel structure CH1c.

In an embodiment, the first channel pad 144 may be provided on the first channel structure CH1 (e.g., the third sub-channel structure CH1c) that penetrates or extends into the gate stacking structure 120 (e.g., the third gate stacking structure 120c) positioned in an upper portion among the plurality of gate stacking structures 120. However, the present disclosure is not limited thereto, and in some embodiments, the first channel pad 144 may be positioned respectively on the first to third sub-channel structures CH1a, CH1b, and CH1c. Accordingly, the first channel pad 144 of the first or second sub-channel structures CH1a or CH1b may be connected to the first channel layer 140 of the second or third sub-channel structures CH1b or CH1c positioned in an upper portion.

In an embodiment, in a plan view, the gate stacking structure 120 may be partitioned into a plurality of parts by the separation structure 136 that extends in a cross direction (e.g., the third direction Z that is a vertical direction) crossing the second substrate 110 penetrates or extends into the gate stacking structure 120.

For example, the separation structure 136 may penetrate or extend into the gate electrode 130 and the cell insulation layer 132 and extend to the second substrate 110. The separation structure 136 extends in a second direction Y in a plan view, and may be provided in a plural quantity such that they may be spaced apart from each other at a predetermined interval in a first direction X.

Accordingly, in a plan view, respective ones of the plurality of gate stacking structures 120 may extend in the second direction Y, and may be spaced apart from each other at a predetermined interval in the first direction X.

By the separation structure 136, the partitioned gate stacking structure 120 may form one memory cell block. However, the present disclosure is not limited thereto, and the range of the memory cell block is not limited thereto.

Due to the high aspect ratio, in a cross-sectional view, the separation structure 136 may have an inclined side surface of which the width decreases toward the second substrate 110. However, a cross-sectional shape of the separation structure 136 is not limited thereto, and a side surface of the separation structure 136 may be perpendicular to the second substrate 110.

In FIG. 1, in a cross-sectional view, the separation structure 136 is shown to have a continuous inclined side surface and not include a bent portion in the first to third gate stacking structures 120a, 120b, and 120c, but is not limited thereto, and the separation structure 136 may include a bent portion in boundary portions between the first gate stacking structure 120a and the second gate stacking structure 120b and between the second gate stacking structure 120b and the third gate stacking structure 120c.

The separation structure 136 may be filled with various insulating materials. For example, the separation structure 136 may include an insulating material such as silicon oxide, silicon nitride, or silicon nitride oxide. However, the present disclosure is not limited thereto, and the structure, shape, material, and the like of the separation structure 136 may be changed in various ways.

A first upper insulation layer 412 and a second upper insulation layer 321 may be sequentially positioned on the gate stacking structure 120, the separation structure 136, and the cell insulation layer 132. The first upper insulation layer 412 and the second upper insulation layer 321 may include different materials. That is, the first upper insulation layer 412 may include a material having etching selectivity with respect to the second upper insulation layer 321. For example, the first upper insulation layer 412 may include a nitride-based material such as silicon nitride and silicon nitride oxide, and the second upper insulation layer 321 may include an oxide-based material such as silicon oxide.

The selection gate electrode 150 may be positioned on the second upper insulation layer 321. The selection gate electrode 150 may be positioned at a higher level than the first channel structure CH1. That is, the first upper insulation layer 412 and the second upper insulation layer 321 may be positioned between the first channel structure CH1 and the selection gate electrode 150.

A thickness of the selection gate electrode 150 may be thicker than a thickness of each of the gate electrodes 130. For example, the thickness of the selection gate electrode 150 may be 5 times thicker than the thickness of each of the gate electrodes 130.

The selection gate electrode 150 may include a different material from the gate electrodes 130. For example, the selection gate electrode 150 may include a semiconductor material such as polysilicon. The selection gate electrode 150 may be a string selection line forming a string select transistor.

An upper portion separation structure 138 penetrates or extends into the selection gate electrode 150 and may extend toward the second substrate 110. The upper portion separation structure 138 may have, in a cross-sectional view, an inclined side surface such that the width narrows as it becomes closer to the second substrate 110 according to the aspect ratio. The upper portion separation structure 138 extends in the second direction Y, and may be provided in a plural quantity such that they may be spaced apart from each other at a predetermined interval in the first direction X.

In an embodiment, each of an upper surface and a bottom surface of the upper separation structure 138 may be positioned at substantially the same level as an upper surface and a bottom surface of the selection gate electrode 150. However, the present disclosure is not limited thereto, and in some embodiments, the upper separation structure 138 may penetrate or extend into the selection gate electrode 150 such that it extends to the second upper insulation layer 321.

The upper portion separation structure 138 may be filled with or include various insulating materials. For example, the upper separation structure 138 may include an insulating material such as silicon oxide, silicon nitride, or silicon nitride oxide. However, the present disclosure is not limited thereto, and the structure, shape, material, and the like of the upper separation structure 138 may be changed in various ways.

The second channel structure CH2 may penetrate or extend into the selection gate electrode 150, and be connected to the first channel pad 144. Each of the second channel structures CH2 may be electrically connected to the first channel structures CH1 through the first channel pad 144. The second channel structure CH2 may be a channel structure forming a string select transistor.

The second channel structure CH2 may have a pillar shape. For example, the second channel structure CH2 may have, in a cross-sectional view, an inclined side surface such that the width narrows as it becomes closer to the second substrate 110 according to the aspect ratio. However, the present disclosure is not limited thereto, and the arrangement, structure, shape, and the like of the second channel structure CH2 may be changed in various ways. For example, in a cross-sectional view, the side surface of the second channel structure CH2 may be perpendicular to the second substrate 110.

In more detail, and as shown in FIG. 3, the second channel structure CH2 may include a second core insulation layer 162, a second channel layer 164, a semiconductor spacer layer 166, and a second gate dielectric layer 168.

The second channel layer 164 may at least partially surround a side surface of the second core insulation layer 162 that is positioned in a central portion of the second channel structure CH2. For example, the second core insulation layer 162 may have a pillar shape, such as a circular cylinder or a polygonal pillar, and may have a planar shape, such as an annular shape. However, the present disclosure is not limited thereto, and in some embodiments, the second core insulation layer 162 may be omitted, and the second channel layer 164 may have a pillar shape. A bottom surface of the second channel layer 164 may be connected to the first channel pad 144. The second channel layer 164 may include a semiconductor material such as polysilicon, and the semiconductor material may be an undoped material, or may be a material including P-type or N-type impurities.

The semiconductor spacer layer 166 may cover or overlap an exterior side of the second channel layer 164. The semiconductor spacer layer 166 may be positioned between the second gate dielectric layer 168 and the second channel layer 164.

The semiconductor spacer layer 166 may be a spacer structure for an etching process, and may function as a channel layer together with the second channel layer 164. The semiconductor spacer layer 166 may include a semiconductor material such as silicon. For example, when the semiconductor spacer layer 166 and the second channel layer 164 include the same material, a boundary between the two components may not be distinguished. However, the present disclosure is not limited thereto, and in some embodiments, the semiconductor spacer layer 166 may be omitted, or may be replaced with a separate spacer layer other than a semiconductor.

The second gate dielectric layer 168 may be disposed between the selection gate electrode 150 and the semiconductor spacer layer 166. That is, the second gate dielectric layer 168 may be positioned on a side surface of the semiconductor spacer layer 166.

In addition, a selection gate insulation pattern 323p may be positioned between the selection gate electrode 150 and the second gate dielectric layer 168. The selection gate insulation pattern 323p may form a portion of a third upper insulation layer 323 to be described later.

In some embodiments, the second gate dielectric layer 168 may include a different structure or different material from the first gate dielectric layer 146. For example, as described above, the first gate dielectric layer 146 may include multiple layers, and the second gate dielectric layer 168 may include a single layer. The second gate dielectric layer 168 may be formed in a single layer including silicon oxide, silicon nitride, silicon oxynitride, or high-k dielectric material.

A second channel pad 175 may cover or overlap upper surfaces of the second core insulation layer 162, the second channel layer 164, and the semiconductor spacer layer 166 of the second channel structure CH2. In addition, the second channel pad 175 may contact the second core insulation layer 162, the second channel layer 164, and the semiconductor spacer layer 166, respectively. The second channel pad 175 may be electrically connected to the second channel layer 164.

The second channel pad 175 may be at least partially surrounded by the second gate dielectric layer 168. For example, a side surface of the second channel pad 175 contacts the second gate dielectric layer 168, and may be surrounded by the second gate dielectric layer 168. That is, the second gate dielectric layer 168 may cover or overlap the side surface of the second channel pad 175. The second channel pad 175 may include polysilicon or doped polysilicon, but is not limited thereto.

The third upper insulation layer 323 may be positioned on the selection gate electrode 150. The third upper insulation layer 323 may cover or overlap the selection gate electrode 150. The third upper insulation layer 323 may cover or overlap a side surface of the second channel structure CH2. An upper surface of the third upper insulation layer 323 may be positioned at a higher level than an upper surface of the second channel pad 175. In addition, the selection gate electrode 150 may include a plurality of selection gate holes 150H penetrating or extending into the selection gate electrode 150, and the third upper insulation layer 323 may fill or be in a selection gate hole 150H of the selection gate electrode 150.

The third upper insulation layer 323 may include various insulating materials. For example, the third upper insulation layer 323 may include at least one of silicon oxide, silicon nitride, and silicon nitride oxide.

The first contact electrode 181 may be positioned on the second channel pad 175 in the cell array region 102. The first contact electrode 181 may be positioned within the third upper insulation layer 323. The first contact electrode 181 may be electrically connected to first and second channel structures CH1 and CH2 through the second channel pad 175. The first contact electrode 181 may be positioned between the second channel pad 175 and a first upper wire structure M1 to be described later. That is, a bottom surface of the first contact electrode 181 may be connected to the second channel pad 175, and an upper surface of the first contact electrode 181 may be connected to the first upper wire structure M1. Accordingly, the first and second channel structures CH1 and CH2 may be electrically connected to the first upper wire structure M1 through the first contact electrode 181.

A second contact electrode 183 may be positioned on the selection gate electrode 150 in the connecting region 104. The second contact electrode 183 may be positioned within the third upper insulation layer 323. The second contact electrode 183 may be electrically connected to the selection gate electrode 150. The second contact electrode 183 may be positioned between the first upper wire structure M1 and the selection gate electrode 150 to be described later. That is, a bottom surface of the second contact electrode 183 may be connected to the selection gate electrode 150, and an upper surface of the second contact electrode 183 may be connected to the first upper wire structure M1. Accordingly, the selection gate electrode 150 may be electrically connected to the first upper wire structure M1 through the second contact electrode 183.

The first and second contact electrodes 181 and 183 may have, in a cross-sectional view, an inclined side surface such that the width narrows as it becomes closer to the second substrate 110 according to the aspect ratio. That is, widths of bottom surfaces of the first and second contact electrodes 181 and 183 may be smaller widths than upper surfaces thereof. However, the arrangement and shape of the first and second contact electrodes 181 and 183 is not limited thereto, and may be changed in various ways.

In an embodiment, the first and second contact electrodes 181 and 183 may include for example, tungsten (W), copper (Cu), aluminum (Al), or the like, but the conductive material is not limited thereto, and the material included in the first and second contact electrodes 181 and 183 may be changed in various ways.

In the connecting region 104, components for connection to the gate electrode 130, the horizontal conductive layers 112 and 114 and/or the second substrate 110, and the circuit region 200 may be positioned. In addition, the connecting region 104 may include a portion where an input/output pad and an input/output connection wiring is positioned.

In more detail, a plurality of gate electrodes 130 may be positioned to extend from the cell array region 102 toward the connecting region 104 in the first direction X. In the connecting region 104, extension lengths of the plurality of gate electrodes 130 according to the first direction X may be sequentially smaller as it is farther from the second substrate 110. For example, the plurality of gate electrodes 130 may be positioned to have a step shape in the connecting region 104.

Here, the plurality of gate electrodes 130 may have a step shape in one direction or a plurality of directions. Accordingly, in the connecting region 104, the plurality of gate electrodes 130 stacked in the vertical direction may be sequentially connected to an upper gate contact portion 182 and/or the through-gate contact portion 184.

The upper gate contact portion 182 may sequentially penetrate or extend into the third upper insulation layer 323, the second upper insulation layer 321, and the first upper insulation layer 412, and may be electrically connected to the gate electrode 130. The upper gate contact portion 182 extends in the second direction Y, and may be provided in a plural quantity such that they may be spaced apart from each other at a predetermined interval in the first direction X.

The upper gate contact portion 182 may penetrate or extend into the selection gate electrode 150. That is, the upper gate contact portion 182 may penetrate or extend into the third upper insulation layer 323 positioned within the selection gate hole 150H of the selection gate electrode 150. Accordingly, the third upper insulation layer 323 may be positioned between upper gate contact portions 182 and between the upper gate contact portion 182 and the selection gate electrode 150, and by the third upper insulation layer 323, the selection gate electrode 150, and the upper gate contact portion 182 may be separated and insulated. However, the present disclosure is not limited thereto, and in some embodiments, an insulation pattern configured separately from the third upper insulation layer 323 may be positioned within the selection gate hole 150H of the selection gate electrode 150.

The upper gate contact portion 182 may include, for example, tungsten (W), copper (Cu), aluminum (Al), or the like, but the material is not limited thereto, and the material included in the upper gate contact portion 182 may be changed in various ways.

In more detail, referring to FIG. 4 together with FIG. 1, a plurality of upper gate contact portions 182 may be electrically connected to each of the upper gate electrode 130U sequentially positioned in an uppermost end of the gate stacking structure 120. The plurality of upper gate contact portions 182 may contact an upper surface of the upper gate electrode 130U.

For example, the upper gate contact portion 182 may include a first upper gate contact portion 182_1 connected to a first upper gate electrode 130U1 positioned at an uppermost end of the gate stacking structure 120, a second upper gate contact portion 182_2 connected to a second upper gate electrode 130U2 positioned below a first upper gate electrode 1310U1, and a third upper gate contact portion 182_3 connected to a third upper gate electrode 130U3 positioned below the second upper gate electrode 130U2.

In some embodiments, each of the upper gate contact portion 182 may include first portions 182_1a, 182_2a, and 182_3a positioned within a third upper gate insulation layer 132c and second portions 182_1b, 182_2b, and 182_3b penetrating or extending into the third upper insulation layer 323, the second upper insulation layer 321, and the first upper insulation layer 412. That is, the first portions 182_1a, 182_2a, and 182_3a and the second portions 182_1b, 182_2b, and 182_3b of the upper gate contact portion 182 may be positioned in different layers, and may have a sequentially stacked shape.

The first portions 182_1a, 182_2a, and 182_3a of the upper gate contact portion 182 may be positioned between the first upper insulation layer 412 and the upper gate electrode 130U, and bottom surfaces of the first portions 182_1a, 182_2a, and 182_3a of the upper gate contact portion 182 may be connected to the upper gate electrode 130U. An upper surface of the second portions 182_1b, 182_2b, and 182_3b of the upper gate contact portion 182 may be positioned at substantially the same level as the upper surface of the third upper insulation layer 323, and may be connected to the first upper wire structure M1. Accordingly, the upper gate electrode 130U and the first upper wire structure M1 may be electrically connected by the upper gate contact portion 182.

Lengths of the first portions 182_1a, 182_2a, and 182_3a of the upper gate contact portion 182 may be different from lengths of the second portions 182_1b, 182_2b, and 182_3b of the upper gate contact portion 182. Here, the length may mean a length according to the third direction Z that is perpendicular to the second substrate 110.

For example, a length of the first portion 182_1a of the first upper gate contact portion 182_1 has a first length D1, a length of the second portion 182_1b of the first upper gate contact portion 182_1 has a second length D2, and the first length D1 may be shorter than the second length D2. The description has been made based on the first upper gate contact portion 182_1, but the description may also be substantially equally applied to the second upper gate contact portion 182_2 and the third upper gate contact portion 182_3.

As described above, since the upper gate electrode 130U positioned in the connecting region 104 has a step shape in a cross-sectional view, a length of the upper gate contact portion 182 connected to each of the upper gate electrode 130U may be different. That is, the upper gate contact portion 182_1 positioned adjacent to the cell array region 102 may be shorter than a length of the upper gate contact portion 182_1 positioned adjacent to the connecting region 104.

In more detail, lengths of the first portions 182_1a, 182_2a, and 182_3a of the upper gate contact portion 182 may be different, and the lengths of the second portions 182_1b, 182_2b, and 182_3b of the upper gate contact portion 182 may be substantially the same. Accordingly, lengths of the plurality of upper gate contact portions 182 may be different.

For example, a length of a first portion 182_2a of the second upper gate contact portion 182_2 is longer than the length of the first portion 182_1a of the first upper gate contact portion 182_1, and a length of a first portion 182_3a of the third upper gate contact portion 182_3 may be longer than a length of the first portion 182_2a of the second upper gate contact portion 182_2. In addition, the length of the second portion 182_1b of the first upper gate contact portion 182_1, a length of the second portion 182_2b of the second upper gate contact portion 182_2, and a length of the second portion 182_3b of the third upper gate contact portion 182_3 may be substantially the same.

Each of the first portions 182_1a, 182_2a, and 182_3a and the second portions 182_1b, 182_2b, and 182_3b of the upper gate contact portion 182 may have, in a cross-sectional view, an inclined side surface such that the width narrows as it becomes closer to the second substrate 110 according to the aspect ratio. That is, widths of the bottom surfaces of the first portions 182_1a, 182_2a, and 182_3a of the upper gate contact portion 182 may have smaller widths than upper surfaces thereof, and widths of bottom surfaces of the second portions 182_1b, 182_2b, and 182_3b of the upper gate contact portion 182 may have smaller widths than upper surfaces thereof.

A width of an upper surface of each of the first portions 182_1a, 182_2a, and 182_3a of the upper gate contact portion 182 may be wider than a width of a bottom surface of each of the second portions 182_1b, 182_2b, and 182_3b of the upper gate contact portion 182.

For example, a width of an upper surface of the first portion 182_1a of the first upper gate contact portion 182_1 may be different from a width of a bottom surface of the second portion 182_1b of the first upper gate contact portion 182_1. The upper surface of the first portion 182_1a of the first upper gate contact portion 182_1 has a first width W1, the bottom surface of the second portion 182_1b of the first upper gate contact portion 182_1 may have a second width W2, and the first width W1 may be larger than the second width W2.

Accordingly, a step difference may occur (e.g., a step portion may be provided) at a boundary portion of the first portion 182_1a and the second portion 182_1b of the first upper gate contact portion 182_1. That is, by a width difference between the first portion 182_1a of the first upper gate contact portion 182_1 and the second portion 182_1b of the first upper gate contact portion 182_1, a bent portion may be included in the boundary portion of the first portion 182_1a and the second portion 182_1b. In other words, a side surface of the first portion 182_1a of the first upper gate contact portion 182_1 and a side surface of the second portion 182_1b of the first upper gate contact portion 182_1 may extend discontinuously. The description has been made based on the first upper gate contact portion 182_1, but the description may also be substantially equally applied to the second upper gate contact portion 182_2 and the third upper gate contact portion 182_3.

The first portions 182_1a, 182_2a, and 182_3a and the second portions 182_1b, 182_2b, and 182_3b of the upper gate contact portion 182 may be integrally formed. That is, since the first portions 182_1a, 182_2a, and 182_3a of the upper gate contact portion 182 and the second portions 182_1b, 182_2b, and 182_3b include the same material, the boundary between the first portions 182_1a, 182_2a, and 182_3a and the second portions 182_1b, 182_2b, and 182_3b of the upper gate contact portion 182 may not be distinguished. However, the present disclosure is not limited thereto, and in some embodiments, since the first portions 182_1a, 182_2a, and 182_3a of the upper gate contact portion 182 and the second portions 182_1b, 182_2b, and 182_3b include different materials, a boundary may be provided between the first portions 182_1a, 182_2a, and 182_3a and the second portions 182_1b, 182_2b, and 182_3b of the upper gate contact portion 182.

In some embodiments, the upper gate contact portion 182 may include a gate barrier pattern (not shown) at least partially surrounding the upper gate contact portion 182. The gate barrier pattern may cover or overlap side surfaces and a bottom surface of the upper gate contact portion 182. However, arrangement relationship of the gate barrier pattern and the upper gate contact portion 182 is not limited thereto, and may be changed in various ways. For example, the gate barrier pattern may cover or overlap side surfaces excluding the bottom surface of the upper gate contact portion 182.

The gate barrier pattern may include a metal layer/metal nitride layer. The metal layer may include, for example, at least one of titanium, tantalum, tungsten, nickel, cobalt and platinum. The metal nitride layer may include, for example, at least one of a titanium nitride layer (TiN), a tantalum nitride layer (TaN), a tungsten nitride layer (WN), a nickel nitride layer (NiN), a cobalt nitride layer (CoN), and a platinum nitride layer (PtN).

In FIG. 1 and FIG. 4, although it is illustrated that the number of the upper gate contact portion 182 is three, the number of the upper gate contact portion 182 is not limited thereto, and may be changed in various ways. For example, the number of the upper gate contact portion 182 may be one or three or more.

In the connecting region 104, the through-gate contact portion 184 may penetrate or extend into the gate stacking structure 120 to be connected to the gate electrode 130, extend to the third lower wire layer 256 of the circuit region 200, and be electrically connected to the circuit region 200. The through-gate contact portion 184 extends in the second direction Y, and may be provided in a plural quantity such that they may be spaced apart from each other at a predetermined interval in the first direction X.

In more detail, referring to FIG. 5 together with FIG. 1, a plurality of through-gate contact portions 184 may sequentially penetrate or extend into insulation layers, the gate stacking structure 120, the horizontal conductive layers 112 and 114, the second substrate 110, and the third circuit insulation layer 236 of the cell region 100 and be electrically connected to the circuit region 200.

A portion of the through-gate contact portion 184 positioned at a higher level than the gate stacking structure 120 may be positioned within the third upper insulation layer 323. That is, a portion of the through-gate contact portion 184 may penetrate or extend into the third upper insulation layer 323 that fills or is in the selection gate hole 150H of the selection gate electrode 150. Accordingly, the selection gate electrode 150 and the through-gate contact portion 184 may be separated and insulated by the third upper insulation layer 323.

In the cell array region 102, the through-gate contact portion 184 may be electrically connected to a connection gate electrode 130c provided with a pad portion WP among the plurality of gate electrodes 130 included in the gate stacking structure 120, and insulated from a remaining gate electrode 130r interposing or extending into a gate insulation pattern 184p.

The pad portion WP of the connection gate electrode 130c may be positioned in an end portion of the connection gate electrode 130c disposed far from the cell array region 102. The through-gate contact portion 184 may be connected to inner side surface of the pad portion WP while penetrating or extending into the pad portion WP of the connection gate electrode 130c. Although not shown FIG. 1 and FIG. 5, the through-gate contact portion 184 may include a connection portion that protrudes toward an inner side surface of the pad portion WP and directly contacts the pad portion WP.

The through-gate contact portion 184 may include a conductive material, for example, may include tungsten (W), copper (Cu), aluminum (Al), or the like, and may further include a diffusion barrier layer. However, the material of the through-gate contact portion 184 is not limited thereto, may be changed in various ways.

The gate insulation pattern 184p may be positioned between the through-gate contact portion 184 and the remaining gate electrode 130r excluding the connection gate electrode 130c. The through-gate contact portion 184 and the remaining gate electrode 130r may be electrically insulated by the gate insulation pattern 184p.

The gate insulation pattern 184p may include an insulating material, for example, at least one of silicon oxide, silicon nitride and silicon nitride oxide, but is not limited thereto.

The first upper wire structure M1 may be positioned on the through-gate contact portion 184. A first side of the through-gate contact portion 184 may be connected to the first upper wire structure M1, a second side of the through-gate contact portion 184 is connected to the third lower wire layer 256 that penetrates or extends into the gate stacking structure 120 or the like and is positioned in an upper region of the circuit region 200, and thereby, the first upper wire structure M1 and the circuit region 200 may be electrically connected.

Accordingly, the degree of design freedom for electrically connecting the cell region 100 and the circuit region 200 may be improved. However, the connection method of the through-gate contact portion 184 and the circuit region 200 shown in FIG. 1 is merely an example, and may be changed in various ways.

In a cross-sectional view, the through-gate contact portion 184 may have an inclined side surface such that the width narrows as it becomes closer to the second substrate 110 according to the aspect ratio, and may include a bent portion in a boundary portion of the plurality of gate stacking structures 120a, 120b, and 120c. In addition, the through-gate contact portion 184 may include a bent portion at a boundary of the first upper insulation layer 412 and the third upper gate insulation layer 132c. However, a cross-sectional shape of the through-gate contact portion 184 is not limited thereto, and may be changed in various ways. For example, the through-gate contact portion 184 may not include a bent portion at the boundary portion of the plurality of gate stacking structures 120a, 120b, and 120c.

As shown in FIG. 5, in some embodiments, each of the plurality of through-gate contact portions 184 penetrates or extends into the gate stacking structure 120, and may include a first portion 184a positioned at a lower level than the bottom surface of the upper gate contact portion 182, and a second portion 184b vertically extending from the first portion 184a of the through-gate contact portion 184 and positioned at a level between the upper surface of the upper gate electrode 130U positioned at a lowermost end among the upper gate electrode 130U and a bottom surface of the first upper insulation layer 412.

In more detail, in some embodiments, an upper surface of the first portion 184a of the through-gate contact portion 184 penetrating or extending into the connection gate electrode 130c and the remaining gate electrode 130r may be positioned at substantially the same level as an upper surface of the third upper gate electrode 130U3 positioned at a lowermost end among the upper gate electrode 130U. That is, the upper surface of the first portion 184a of the through-gate contact portion 184 may be positioned at substantially the same level as a bottom surface of the third upper gate contact portion 182_3 contacting the upper surface of the third upper gate electrode 130U3. Accordingly, the first portion 184a of the through-gate contact portion 184 may be positioned at a lower level than the bottom surface of the third upper gate contact portion 182_3 contacting third upper gate electrode 130U3 positioned at a lowermost end among the upper gate electrode 130U.

The second portion 184b of the through-gate contact portion 184 may extend from the first portion 184a toward the first upper insulation layer 412, and may be positioned at a level between the upper surface of the third upper gate electrode 130U3 positioned at a lowermost end among the upper gate electrode 130U and the bottom surface of the first upper insulation layer 412. That is, the second portion 184b of the through-gate contact portion 184 may be positioned at substantially the same level as the first portion 182_3a of the third upper gate contact portion 182_3 connected to the third upper gate electrode 130U3, and may overlap in the first direction X, which is a horizontal direction. In other words, each of a bottom surface and an upper surface of the second portion 184b of the through-gate contact portion 184 may be positioned at substantially the same level as each of a bottom surface and an upper surface of the first portion 182_3a of the third upper gate contact portion 182_3.

A side surface 184a_S of the first portion 184a of the through-gate contact portion 184 may have a different inclination from a side surface 184b_S of the second portion 184b. That is, an inclination of the side surface 184a_S of the first portion 184a may be steeper than an inclination of the side surface 184b_S of the second portion 184b. In other words, the slope of the side surface 184b_S of the second portion 184b may be gentler than slope of the side surface 184a_S of the first portion 184a. Here, the inclination or slope may mean, for example, an inclination with respect to the upper surface of the second substrate 110.

The inclination of the side surface 184a_S of the first portion 184a and an inclination of a side surface 184b_S of the second portion 184b may be different based on a line X1-X1′ that is a virtual/imaginary extension line according to the first direction X positioned on the upper surface of the third upper gate electrode 130U3 positioned at a lowermost end among the upper gate electrode 130U. That is, the line X1-X1′ that is a virtual/imaginary extension line may be positioned at substantially the same level as a bottom surface of the first portion 182_3a of the third upper gate contact portion 182_3 connected to the third upper gate electrode 130U3.

This may result from that, in the process step for forming the first to third gate contact portions 182_1, 182_2, and 182_3, the width of the contact hole in which the second portion 184b of the through-gate contact portion 184 is positioned is expanded. A detailed description of this process is provided later.

In FIG. 1 and FIG. 5, the arrangement relationship of the first portion 184a and the second portion 184b of the through-gate contact portion 184 and the relationship of inclination or slope of side surfaces of the first portion 184a and the second portion 184b of the through-gate contact portion 184 are described based on the third upper gate electrode 130U3 positioned at a lowermost end among the upper gate electrode 130U, but it is not limited thereto.

For example, in some embodiments, when the number of the upper gate electrode 130U is formed as one or two, the arrangement relationship of the first portion 184a and the second portion 184b of the third upper gate electrode 130U3 and the through-gate contact portion 184, the description with respect to the relationship of inclinations or slopes of side surfaces of the first portion 184a and the second portion 184b of the through-gate contact portion 184 may also be substantially equally applied to the relationship with respect to the first upper gate electrode 130U1 or the second upper gate electrode 130U2.

In the connecting region 104, the source contact portion 186 and the through-contact portion 188 may be positioned in an outer side of the gate stacking structure 120. In the connecting region 104, the source contact portion 186 and the through-contact portion 188 may sequentially penetrate or extend into insulation layers, first to third upper gate insulation layers 132a, 132b, and 132c, the second substrate 110, and the third circuit insulation layer 236 of the cell region 100, and extend to the third lower wire layer 256 of the circuit region 200, so as to be electrically connected to the circuit region 200.

Since the source contact portion 186 is connected to the third lower wire layer 256, and the second substrate 110 is connected to the third lower wire layer 256 through the contact hole 236H, the source contact portion 186 and the second substrate 110 may be electrically connected through the third lower wire layer 256. However, the connection relationship of the source contact portion 186 and the second substrate 110 is not limited thereto, and may be changed in various ways. For example, the source contact portion 186 may be directly connected to the second substrate 110.

A portion of the through-contact portion 188 and the source contact portion 186 positioned at a higher level than the gate stacking structure 120 may be positioned within the third upper insulation layer 323. That is, a portion of the source contact portion 186 and the through-contact portion 188 may penetrate or extend into the third upper insulation layer 323 that fills the selection gate hole 150H of the selection gate electrode 150. Accordingly, the selection gate electrode 150 may be separated and insulated from the source contact portion 186 and the through-contact portion 188 by the third upper insulation layer 323.

In FIG. 1, in a cross-sectional view, the source contact portion 186 and/or the through-contact portion 188 may have an inclined side surface such that the width narrows as it becomes closer to the second substrate 110 according to the aspect ratio, and may include a bent portion in the boundary portion of the plurality of gate stacking structures 120a, 120b, and 120c. In addition, the source contact portion 186 and/or the through-contact portion 188 may include a bent portion at the boundary of the first upper insulation layer 412 and the third upper gate insulation layer 132c. However, cross-sectional shapes of the source contact portion 186 and the through-contact portion 188 are not limited thereto, and may be changed in various ways. For example, the source contact portion 186 and/or the through-contact portion 188 may not include a bent portion at the boundary portion of the plurality of gate stacking structures 120a, 120b, and 120c.

In addition, in the same way as the through-gate contact portion 184, a portion of a portion and/or the through-contact portion 188 of the source contact portion 186 may include a portion where the inclination or slope of the side surface changes based on an upper surface of the third upper gate electrode 130U3 (refer to FIG. 5) positioned at a lowermost end among the upper gate electrode 130U.

The source contact portion 186 and the through-contact portion 188 may include a conductive material, for example, tungsten (W), copper (Cu), aluminum (Al), or the like. However, the material is not limited thereto, and the material included in and the source contact portion 186 and the through-contact portion 188 may be changed in various ways.

The first upper wire structure M1 may be positioned on the source contact portion 186 and the through-contact portion 188. First sides of the source contact portion 186 and the through-contact portion 188 may be connected to the first upper wire structure M1, and second sides of the source contact portion 186 and the through-contact portion 188 penetrate or extend into the first to third upper gate insulation layers 132a, 132b, and 132c or the like and are connected to the third lower wire layer 256 positioned in the upper region of the circuit region 200, and thereby, the first upper wire structure M1 and the circuit region 200 may be electrically connected.

In some embodiments, each of the through-gate contact portion 184, the source contact portion 186, and the through-contact portion 188 may include a gate barrier pattern (not shown) at least partially surrounding the through-gate contact portion 184, the source contact portion 186, and the through-contact portion 188. The gate barrier pattern may cover or overlap side surfaces and bottom surface of the through-gate contact portion 184, the source contact portion 186, and the through-contact portion 188. However, the arrangement relationship of the gate barrier pattern and the through-gate contact portion 184, the source contact portion 186, and the through-contact portion 188 is not limited thereto, and may be changed in various ways. For example, the gate barrier pattern may cover or overlap side surfaces excluding bottom surfaces of the through-gate contact portion 184, the source contact portion 186, and the through-contact portion 188.

The gate barrier pattern may include a metal layer/metal nitride layer. The metal layer may include, for example, at least one of titanium, tantalum, tungsten, nickel, cobalt and platinum. The metal nitride layer may include, for example, at least one of a titanium nitride layer (TiN), a tantalum nitride layer (TaN), a tungsten nitride layer (WN), a nickel nitride layer (NiN), a cobalt nitride layer (CoN), and a platinum nitride layer (PtN).

The fourth to sixth upper insulation layers 325, 327, and 329 may be sequentially stacked on the third upper insulation layer 323. The fourth to sixth upper insulation layers 325, 327, and 329 may include, for example, at least one of silicon oxide, silicon nitride, and silicon nitride oxide. However, the material is not limited thereto, and the material included in and the fourth to sixth upper insulation layers 325, 327, and 329 may be changed in various ways.

First to third upper wire structures M1, M2, and M3 may be positioned within the fourth to sixth upper insulation layers 325, 327, and 329, respectively. The first to third upper wire structures M1, M2, and M3 may include a conductive material such as tungsten (W), copper (Cu), aluminum (Al), or the like, and may be electrically connected to the first and second contact electrodes 181 and 183 and contact portions 182, 184, 186, and 188.

As described above, the first upper wire structure M1 positioned within a fourth upper insulation layer 325 may be electrically connected to first and second contact electrodes 181 and 183 and the contact portions 182, 184, 186, and 188.

A second upper wire structure M2 positioned within a fifth upper insulation layer 327 may be electrically connected to the first upper wire structure M1, and a third upper wire structure M3 positioned within a sixth upper insulation layer 329 may be electrically connected to the second upper wire structure M2.

Accordingly, the first to third upper wire structures M1, M2, and M3 may be connected to the first and second channel structures CH1 and CH2 through the first contact electrode 181, connected to the selection gate electrode 150 through the second contact electrode 183, and connected to the circuit region 200 through the contact portions 182, 184, 186, and 188.

Portions of the first to third upper wire structures M1, M2, and M3 may be bit lines connected to the first contact electrode 181. The bit lines may be electrically connected to the first and second channel structures CH1 and CH2 through the first contact electrode 181.

According to a semiconductor device according to an embodiment, since the gate stacking structure 120 and the upper gate contact portion 182 connected to the upper gate electrode 130U and/or the contact portions 184, 186, and 188 penetrating or extending into the cell insulation layer 132 are formed by the same process step, the process may be simplified compared to the case of performing a separate process in order to form the upper gate contact portion 182, and accordingly, productivity of the semiconductor device may be improved.

In addition, since the upper gate contact portion 182 and the contact portions 184, 186, and 188 are formed by substantially the same process step, the distribution of the upper gate contact portion 182 and the contact portions 184, 186, and 188 may be improved, such that the upper gate contact portion 182 and the contact portions 184, 186, and 188 may be stably formed, and accordingly, a semiconductor device having improved reliability may be provided.

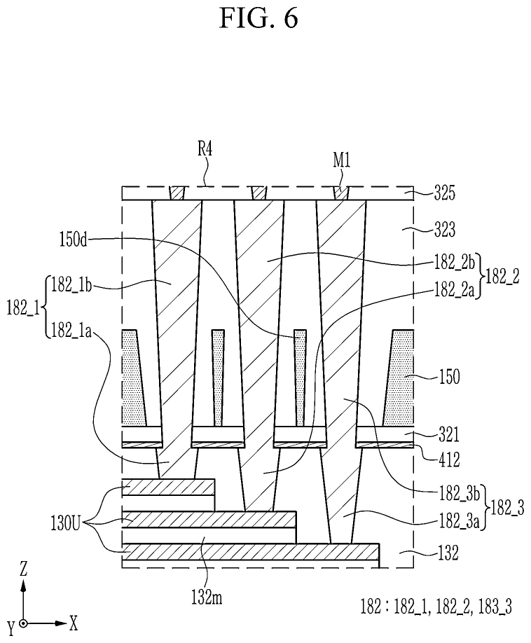

Hereinafter, referring to FIG. 6 to FIG. 10, a semiconductor device according to various embodiments will be described. In the following embodiments, same reference numerals refer to components identical to those of the previously described embodiments, and redundant descriptions will be omitted or simplified, and the description will focus on differences.

FIG. 6 to FIG. 9 are partial enlarged views showing cross-sections of a semiconductor device according to some embodiments.

In more detail, FIG. 6 to FIG. 9 are drawings showing regions R4 to R7 corresponding to the region R2 of FIG. 1.

According to an embodiment shown in FIG. 6, unlike an embodiment shown in FIG. 4, a dummy gate electrode 150d positioned between the plurality of upper gate contact portions 182 is further included.

In more detail, the dummy gate electrode 150d may be positioned between the plurality of upper gate contact portions 182 arranged to be spaced apart at a predetermined interval along the first direction X. The dummy gate electrode 150d may be positioned within the third upper insulation layer 323. Each of an upper surface and a bottom surface of the dummy gate electrode 150d may be positioned at substantially the same level as the upper surface and the bottom surface of the selection gate electrode 150. That is, the dummy gate electrode 150d may be positioned at substantially the same level as the selection gate electrode 150.

The dummy gate electrode 150d may have, in a cross-sectional view, an inclined side surface such that the width narrows as it becomes closer to the second substrate 110 according to the aspect ratio. However, a cross-sectional shape of the dummy gate electrode 150d is not limited thereto, and may be changed in various ways.

The dummy gate electrode 150d may be positioned between the second portions 182_1b, 182_2b, and 182_3b of the upper gate contact portion 182, respectively. For example, the dummy gate electrode 150d may be positioned between the second portion 182_1b of the first upper gate contact portion 182_1 and the second portion 182_2b of the second upper gate contact portion 182_2 and between the second portion 182_2b of the second upper gate contact portion 182_2 and the second portion 182_3b of the third upper gate contact portion 182_3, respectively.

Accordingly, the selection gate electrode 150 and the dummy gate electrode 150d may be positioned at both sides of the second portion 182_1b of the first upper gate contact portion 182_1, the dummy gate electrode 150d may be positioned at both sides of the second portion 182_2b of the second upper gate contact portion 182_2, and the selection gate electrode 150 and the dummy gate electrode 150d may be positioned at both sides of the second portion 182_3b of the third upper gate contact portion 182_3.

The dummy gate electrode 150d may be formed together in the process step for patterning the conductive material in order to form the selection gate electrode 150. For example, the dummy gate electrode 150d may be configured separately from the selection gate electrode 150, and the dummy gate electrode 150d may be electrically floating. However, the present disclosure is not limited thereto, and as another example, the dummy gate electrode 150d may form a portion of the selection gate electrode 150, and substantially the same voltage as the selection gate electrode 150 may be applied to the dummy gate electrode 150d.

When the selection gate electrode 150 and the dummy gate electrode 150d are formed together, the dummy gate electrode 150d may include the same material as the selection gate electrode 150. For example, the dummy gate electrode 150d may include a semiconductor material such as polysilicon. However, the present disclosure is not limited thereto, and the dummy gate electrode 150d may be formed through a separate process from the selection gate electrode 150. Accordingly, the dummy gate electrode 150d may include a different material from the selection gate electrode 150.

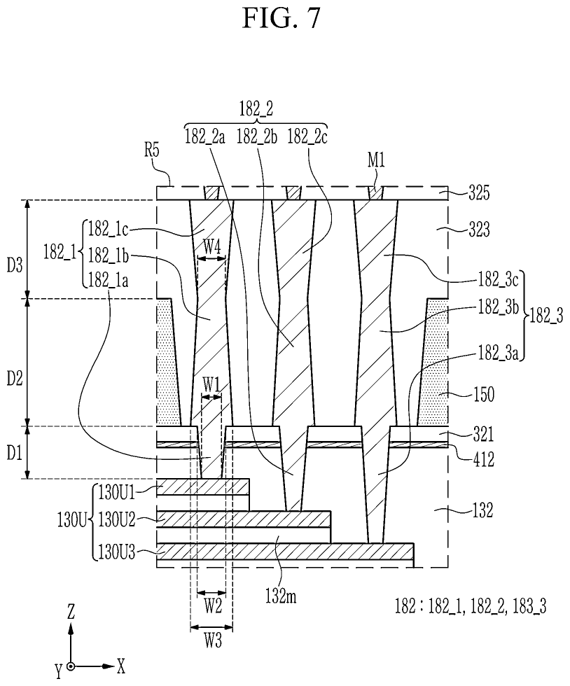

According to an embodiment shown in FIG. 7 to FIG. 9, the difference lies in that the shape and structure are different from those of the upper gate contact portion 182 according to an embodiment shown in FIG. 4.

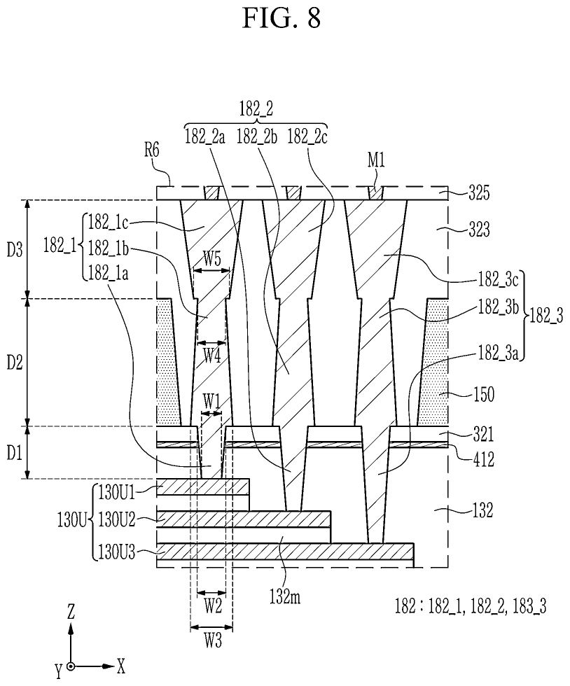

In more detail, referring to FIG. 7 and FIG. 8, each of the upper gate contact portion 182 may include the first portions 182_1a, 182_2a, and 182_3a sequentially penetrating or extending into the second upper insulation layer 321, the first upper insulation layer 412, and the cell insulation layer 132 and connected to the upper gate electrode 130U, the second portions 182_1b, 182_2b, and 182_3b positioned within the third upper insulation layer 323 and having an upper surface and a bottom surface that are positioned at substantially the same level as the upper surface and the bottom surface of the selection gate electrode 150, and third portions 182_1c, 182_2c, and 182_3c positioned within the third upper insulation layer 323 and positioned at a higher level than the selection gate electrode 150. That is, the first portions 182_1a, 182_2a, and 182_3a, the second portions 182_1b, 182_2b, and 182_3b, and the third portions 182_1c, 182_2c, and 182_3c of the upper gate contact portion 182 are positioned at different levels, and may have a sequentially stacked shape.

As described above, since the upper gate electrode 130U positioned in the connecting region 104 has a step shape in a cross-sectional view, the length of the upper gate contact portion 182 connected to each of the upper gate electrode 130U may be different. That is, the upper gate contact portion 182 positioned adjacent to the cell array region 102 may be shorter than the length of the upper gate contact portion 182 positioned adjacent to the connecting region 104. Here, the length may mean a length according to the third direction Z that is perpendicular to the second substrate 110.

In more detail, the lengths of the first portions 182_1a, 182_2a, and 182_3a of the upper gate contact portion 182 may be different, and lengths of each of the second portions 182_1b, 182_2b, and 182_3b and each of the third portions 182_1c, 182_2c, and 182_3c of the upper gate contact portion 182 may be substantially the same. Accordingly, the lengths of the plurality of upper gate contact portions 182 may be different.

For example, the length of the first portion 182_2a of the second upper gate contact portion 182_2 is longer than the length of the first portion 182_1a of the first upper gate contact portion 182_1, and a length of the first portion 182_3a of the third upper gate contact portion 182_3 may be longer than the length of the first portion 182_2a of the second upper gate contact portion 182_2.

In some embodiments, the lengths of the first portions 182_1a, 182_2a, and 182_3a, the lengths of the second portions 182_1b, 182_2b, and 182_3b, and the lengths of the third portions 182_1c, 182_2c, and 182_3c of the upper gate contact portion 182 may be different.

For example, the length of the first portion 182_1a of the first upper gate contact portion 182_1 has the first length D1, the length of the second portion 182_1b has the second length D2, and a length of a third portion 182_1c may have a third length D3. The second length D2 may be longer than the first length D1 and the third length D3, and the third length D3 may be longer than the first length D1. That is, the second length D2 may be the longest, and the first length D1 may be the shortest. However, the lengths are not limited thereto, and the relationship of the first length D1, the second length D2, and the third length D3 may be changed in various ways. For example, the second length D2 and the third length D3 may be substantially the same, or the third length D3 may be longer than the second length D2.

In addition, as described above, since the lengths of the first portions 182_1a, 182_2a, and 182_3a of the upper gate contact portion 182 are different, the length relationship between first to third portions 182_1a, 182_1b, and 182_1c of the first upper gate contact portion 182_1, the length relationship between first to third portions 182_2a, 182_2b, and 182_2c of the second upper gate contact portion 182_2, and the length relationship between first to third portions 182_3a, 182_3b, and 182_3c of the third upper gate contact portion 182_3 may be changed in various ways.

Each of the first portions 182_1a, 182_2a, and 182_3a and the third portions 182_1c, 182_2c, and 182_3c of the upper gate contact portion 182 may have, in a cross-sectional view, an inclined side surface such that the width narrows as it becomes closer to the second substrate 110 according to the aspect ratio, and the second portions 182_1b, 182_2b, and 182_3b of the upper gate contact portion 182 may have, in a cross-sectional view, an inclined side surface such that the width is wider as it becomes closer to the second substrate 110 according to the aspect ratio.

In some embodiments, a bottom surface of the first portion 182_1a of the first upper gate contact portion 182_1 has the first width W1, and an upper surface may have the second width W2. The bottom surface of the second portion 182_1b of the first upper gate contact portion 182_1 may have a third width W3. An upper surface of the second portion 182_1b and a bottom surface of the third portion 182_1c of the first upper gate contact portion 182_1 may have a fourth width W4.

For example, as described above, the width of the first portion 182_1a of the first upper gate contact portion 182_1 is narrower as it gets closer to the second substrate 110 according to the aspect ratio, and accordingly, the first width W1 may be smaller than the second width W2. In addition, the first width W1 and the second width W2 may be smaller than the third width W3. Accordingly, a step difference may occur (e.g., a step portion may be provided) at the boundary portion of the first portion 182_1a and the second portion 182_1b of the first upper gate contact portion 182_1. That is, by a width difference of between the first portion 182_1a of the first upper gate contact portion 182_1 and the second portion 182_1b of the first upper gate contact portion 182_1, a bent portion may be included in a boundary portion between the first portion 182_1a and the second portion 182_1b.

As described above, in a cross-sectional view, the width of the second portion 182_1b of the first upper gate contact portion 182_1 is wider as it gets closer to the second substrate 110 according to the aspect ratio, and accordingly, the third width W3 may be wider than the fourth width W4.

In addition, the upper surface of the second portion 182_1b and the bottom surface of the third portion 182_1c of the first upper gate contact portion 182_1 may have substantially the same fourth width W4. Accordingly, unlike the boundary portion of the first portion 182_1a and the second portion 182_1b of the first upper gate contact portion 182_1, a step difference (e.g., a step portion) or bent portion may not be included in a boundary portion of the second portion 182_1b and the third portion 182_1c of the first upper gate contact portion 182_1.

Since the second portion 182_1b and the third portion 182_1c of the first upper gate contact portion 182_1 have different side surface inclinations, an inclination of a side surface of the upper gate contact portion 182 may be changed from a normal tapered inclination to a reverse tapered inclination based on the boundary portion of the second portion 182_1b and the third portion 182_1c of the first upper gate contact portion 182_1. However, a relationship of widths of the upper surface of the second portion 182_1b and the bottom surface of the third portion 182_1c of the first upper gate contact portion 182_1 is not limited thereto, and may be changed in various ways.

For example, as shown in FIG. 8, the upper surface of the second portion 182_1b of the first upper gate contact portion 182_1 has the fourth width W4, and the bottom surface of the third portion 182_1c may have a fifth width W5 larger than the fourth width W4. As such, when the upper surface of the second portion 182_1b and the bottom surface of the third portion 182_1c of the first upper gate contact portion 182_1 have a width difference, the boundary portion of the second portion 182_1b and the third portion 182_1c of the first upper gate contact portion 182_1 may include a step difference (e.g., a step portion) or a bent portion, the same as in the boundary portion of the first portion 182_1a and the second portion 182_1b of the first upper gate contact portion 182_1.

In addition, the first width WI may be smaller than the fourth width W4. That is, a width of the bottom surface of the first portion 182_1a of the first upper gate contact portion 182_1 may be smaller than a width of the boundary portion of the second portion 182_1b and the third portion 182_1c.

The relationship of the first width WI to the fourth width W4 is merely an example, and the relationship of the first width W1 to the fourth width W4 may be changed in various ways. In addition, although the above description has been made based on the first upper gate contact portion 182_1, the description with respect to may be substantially equally applied to the second upper gate contact portion 182_2 and the third upper gate contact portion 182_3.

In some embodiments, the first portions 182_1a, 182_2a, and 182_3a, the second portions 182_1b, 182_2b, and 182_3b, and the third portions 182_1c, 182_2c, and 182_3c of the upper gate contact portion 182 may be integrally formed. That is, since the first portions 182_1a, 182_2a, and 182_3a, the second portions 182_1b, 182_2b, and 182_3b, and the third portions 182_1c, 182_2c, and 182_3c of the upper gate contact portion 182 include the same material, a boundary between the first portions 182_1a, 182_2a, and 182_3a and the second portions 182_1b, 182_2b, and 182_3b of the upper gate contact portion 182 and a boundary between the second portions 182_1b, 182_2b, and 182_3b and the third portions 182_1c, 182_2c, and 182_3c of the upper gate contact portion 182 may not be distinguished. However, the present disclosure is not limited thereto, and a portion of the first portions 182_1a, 182_2a, and 182_3a, the second portions 182_1b, 182_2b, and 182_3b, and the third portions 182_1c, 182_2c, and 182_3c of the upper gate contact portion 182 may include different materials.

In some embodiments, the first portions 182_1a, 182_2a, and 182_3a and the second portions 182_1b, 182_2b, and 182_3b of the upper gate contact portion 182 may include the same material, and the third portions 182_1c, 182_2c, and 182_3c may include different materials. For example, the first portions 182_1a, 182_2a, and 182_3a and the second portions 182_1b, 182_2b, and 182_3b of the upper gate contact portion 182 may include the same material (e.g., a semiconductor material such as polysilicon) as the selection gate electrode 150, and the third portions 182_1c, 182_2c, and 182_3c may include tungsten (W), copper (Cu), aluminum (Al), or the like.

Accordingly, a boundary between the first portions 182_1a, 182_2a, and 182_3a and the second portions 182_1b, 182_2b, and 182_3b of the upper gate contact portion 182 may not be distinguished, and a boundary may be provided between the second portions 182_1b, 182_2b, and 182_3b and the third portions 182_1c, 182_2c, and 182_3c.

In some embodiments, and as shown in FIG. 6, the dummy gate electrode 150d may be positioned between the plurality of upper gate contact portions 182. For example, the dummy gate electrode 150d may be positioned between the second portion 182_1b of the first upper gate contact portion 182_1 and the second portion 182_2b of the second upper gate contact portion 182_2 and the second portion 182_1b and between the second portion 182_2b of the second upper gate contact portion 182_2 and the second portion 182_3b of the third upper gate contact portion 182_3, respectively.

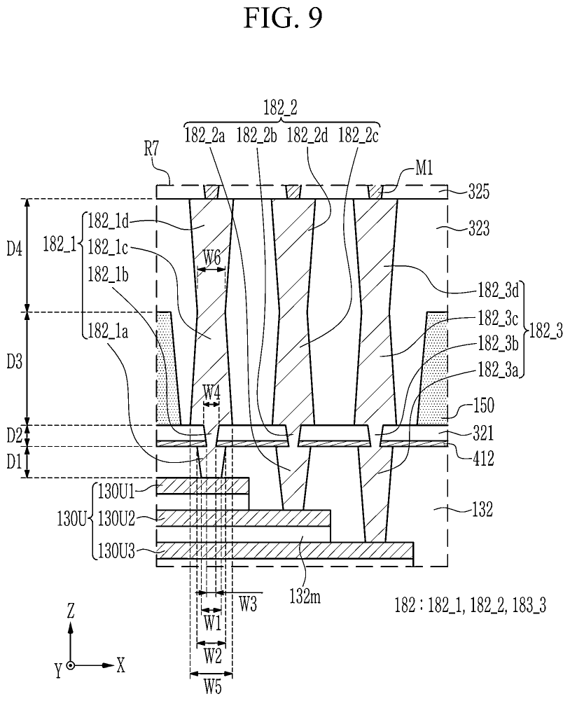

Referring to FIG. 9, each of the upper gate contact portion 182 may include the first portions 182_1a, 182_2a, and 182_3a positioned within the third upper gate insulation layer 132c and connected to the upper gate electrode 130U, the second portions 182_1b, 182_2b, and 182_3b sequentially penetrating or extending into the second upper insulation layer 321 and the first upper insulation layer 412, the third portions 182_1c, 182_2c, and 182_3c positioned within the third upper insulation layer 323 and having an upper surface and a bottom surface positioned at substantially the same level as the upper surface and the bottom surface of the selection gate electrode 150, respectively, and fourth portions 182_1d, 182_2d, and 182_3d positioned at a higher level than the selection gate electrode 150. That is, the first portions 182_1a, 182_2a, and 182_3a, the second portions 182_1b, 182_2b, and 182_3b, the third portions 182_1c, 182_2c, and 182_3c, and the fourth portions 182_1d, 182_2d, and 182_3d of the upper gate contact portion 182 are positioned at different levels, and may have a sequentially stacked shape.

As described above, since the upper gate electrode 130U positioned in the connecting region 104 has a step shape in a cross-sectional view, the length of the upper gate contact portion 182 connected to each of the upper gate electrode 130U may be different. That is, the upper gate contact portion 182 positioned adjacent to the cell array region 102 may be shorter than the length of the upper gate contact portion 182 positioned adjacent to the connecting region 104. Here, the length may mean a length according to the third direction Z that is perpendicular to the second substrate 110.

In more detail, the lengths of the first portions 182_1a, 182_2a, and 182_3a of the upper gate contact portion 182 may be different, and the lengths of the second portions 182_1b, 182_2b, and 182_3b, the third portions 182_1c, 182_2c, and 182_3c, and the fourth portions 182_1d, 182_2d, and 182_3d of the upper gate contact portion 182 may be substantially the same. Accordingly, the lengths of the plurality of upper gate contact portions 182 may be different.

For example, the length of the first portion 182_2a of the second upper gate contact portion 182_2 is longer than the length of the first portion 182_1a of the first upper gate contact portion 182_1, and the length of the first portion 182_3a of the third upper gate contact portion 182_3 may be longer than the length of the first portion 182_2a of the second upper gate contact portion 182_2.

In some embodiments, the lengths of the first portions 182_1a, 182_2a, and 182_3a, the lengths of the second portions 182_1b, 182_2b, and 182_3b, the third portions 182_1c, 182_2c, and 182_3c, and lengths of the fourth portions 182_1d, 182_2d, and 182_3d of the upper gate contact portion 182 may be different.

For example, the length of the first portion 182_1a of the first upper gate contact portion 182_1 has the first length D1, the length of the second portion 182_1b has the second length D2, a length of the third portion 182_1c has the third length D3, and a length of a fourth portion 181_1d may have a fourth length D4.

The third length D3 may be longer than the first length D1, the second length D2, and the fourth length D4, and the fourth length D4 may be longer than the first length D1 and the second length D2. In addition, the first length D1 may be longer than the second length D2. That is, the third length D3 may be the longest, and the second length D2 may be the shortest. However, the present disclosure is not limited thereto, and the relationship of the first length D1, the second length D2, the third length D3, and the fourth length D4 may be changed in various ways.

In addition, as described above, since the lengths of the first portions 182_1a, 182_2a, and 182_3a of the upper gate contact portion 182 are different, the length relationship between first to fourth portions 182_1a, 182_1b, 182_1c, and 182_1d of the first upper gate contact portion 182_1, the length relationship between first to fourth portions 182_2a, 182_2b, 182_2c, and 182_2d of the second upper gate contact portion 182_2, and the length relationship between first to fourth portions 182_3a, 182_3b, 182_3c, and 182_3d of the third upper gate contact portion 182_3 may be changed in various ways.

Each of the first portions 182_1a, 182_2a, and 182_3a, the second portions 182_1b, 182_2b, and 182_3b, and the fourth portions 182_1d, 182_2d, and 182_3d of the upper gate contact portion 182 may have an inclined side surface such that, in a cross-sectional view, the width narrows as it becomes closer to the second substrate 110 according to the aspect ratio, and the third portions 182_1c, 182_2c, and 182_3c of the upper gate contact portion 182 may have an inclined side surface such that, in a cross-sectional view, the width is wider as it gets closer to the second substrate 110 according to the aspect ratio.

In some embodiments, the bottom surface of the first portion 182_1a of the first upper gate contact portion 182_1 has the first width W1, and the upper surface may have the second width W2. The bottom surface of the second portion 182_1b of the first upper gate contact portion 182_1 has the third width W3, and the upper surface may have the fourth width W4. The bottom surface of the third portion 182_1c of the first upper gate contact portion 182_1 has the fifth width W5, and an upper surface of the third portion 182_1c and the bottom surface of the fourth portion 182_1d of the first upper gate contact portion 182_1 may have a sixth width W6.

For example, the width of the first portion 182_1a of the first upper gate contact portion 182_1 narrows as it gets closer to the second substrate 110 according to the aspect ratio as described above, and accordingly, the first width W1 may be smaller than the second width W2. The width of the second portion 182_1b of the first upper gate contact portion 182_1 narrows as it gets closer to the second substrate 110 according to the aspect ratio as described above, and accordingly, the third width W3 may be smaller than the fourth width W4. In addition, the second width W2 may be larger than the first width W1, the third width W3, and the fourth width W4.

Accordingly, a step difference may occur (e.g., a step portion may be provided) at the boundary portion of the first portion 182_1a and the second portion 182_1b of the first upper gate contact portion 182_1. That is, by a width difference between the first portion 182_1a of the first upper gate contact portion 182_1 and the second portion 182_1b of the first upper gate contact portion 182_1, a bent portion or step difference may be included (e.g., a step portion may be provided) in the boundary portion of the first portion 182_1a and the second portion 182_1b.

As described above, in a cross-sectional view, the width of the third portion 182_1c of the first upper gate contact portion 182_1 is wider as it gets closer to the second substrate 110 according to the aspect ratio, and accordingly, the fifth width W5 may be wider than the sixth width W6.

The fifth width W5 may be larger than the first width W1 to the fourth width W4. Accordingly, a bent portion or step difference may occur (e.g., a step portion may be provided) at the boundary portion of the second portion 182_1b and the third portion 182_1c of the first upper gate contact portion 182_1. That is, by a width difference of the upper surface of the second portion 182_1b and the bottom surface of the third portion 182_1c of the first upper gate contact portion 182_1, a bent portion may be included in the boundary portion of the second portion 182_1b and the third portion 182_1c.

In addition, the upper surface of the third portion 182_1c and a bottom surface of the fourth portion 182_1d of the first upper gate contact portion 182_1 may have substantially the same sixth width W6. Accordingly, unlike the boundary portion of the first portion 182_1a and the second portion 182_1b and the boundary portion of the second portion 182_1b and the third portion 182_1c of the first upper gate contact portion 182_1, a step difference (e.g., a step portion) or bent portion may not be included in a boundary portion of the third portion 182_1c and the fourth portion 182_1d of the first upper gate contact portion 182_1. However, a relationship of widths of the upper surface of the third portion 182_1c and the bottom surface of the fourth portion 182_1d of the first upper gate contact portion 182_1 is not limited thereto, and may be changed in various ways. For example, the upper surface of the third portion 182_1c of the first upper gate contact portion 182_1 may have width smaller than the bottom surface of the fourth portion 182_1d.

In addition, the sixth width W6 may be larger than the first width W1, the third width W3, and the fourth width W4. That is, a width of the boundary portion of the third portion 182_1c and the fourth portion 182_1d of the first upper gate contact portion 182_1 may be larger than the width of the bottom surface of the first portion 182_1a, and may be larger than a width of the upper surface and a width of the bottom surface of the second portion 182_1b.

The relationship of the first width WI to the sixth width W6 is not limited thereto, and relationship of the first width W1 to the sixth width W6 may be changed in various ways. In addition, although the above description has been made based on the first upper gate contact portion 182_1, the description with respect to may be substantially equally applied to the second upper gate contact portion 182_2 and the third upper gate contact portion 182_3.

In some embodiments, the first portions 182_1a, 182_2a, and 182_3a, the second portions 182_1b, 182_2b, and 182_3b, and the third portions 182_1c, 182_2c, and 182_3c, and the fourth portions 182_1d, 182_2d, and 182_3d of the upper gate contact portion 182 may be integrally formed. That is, since the first portions 182_1a, 182_2a, and 182_3a, the second portions 182_1b, 182_2b, and 182_3b, the third portions 182_1c, 182_2c, and 182_3c, and the fourth portions 182_1d, 182_2d, and 182_3d of the upper gate contact portion 182 includes the same material, boundaries between the first portions 182_1a, 182_2a, and 182_3a and the second portions 182_1b, 182_2b, and 182_3b of the upper gate contact portion 182, between the second portions 182_1b, 182_2b, and 182_3b and the third portions 182_1c, 182_2c, and 182_3c, and between the third portions 182_1c, 182_2c, and 182_3c and the fourth portions 182_1d, 182_2d, and 182_3d may not be distinguished. However, the present disclosure is not limited thereto, and a portion of the first portions 182_1a, 182_2a, and 182_3a, the second portions 182_1b, 182_2b, and 182_3b, the third portions 182_1c, 182_2c, and 182_3c, and the fourth portions 182_1d, 182_2d, and 182_3d of the upper gate contact portion 182 may include different materials.

In some embodiments, the first portions 182_1a, 182_2a, and 182_3a, the second portions 182_1b, 182_2b, and 182_3b, and the third portions 182_1c, 182_2c, and 182_3c of the upper gate contact portion 182 may include the same material, and the fourth portions 182_1d, 182_2d, and 182_3d may include different materials. For example, the first portions 182_1a, 182_2a, and 182_3a, the second portions 182_1b, 182_2b, and 182_3b, and the third portions 182_1c, 182_2c, and 182_3c of the upper gate contact portion 182 may include the same material (e.g., a semiconductor material such as polysilicon) as the selection gate electrode 150, and the fourth portions 182_1d, 182_2d, and 182_3d may include tungsten (W), copper (Cu), aluminum (Al), or the like.

Accordingly, the boundary between the first portions 182_1a, 182_2a, and 182_3a to the third portions 182_1c, 182_2c, and 182_3c the upper gate contact portion 182 may not be distinguished, and a boundary may be provided between the third portions 182_1c, 182_2c, and 182_3c and the fourth portions 182_1d, 182_2d, and 182_3d.

As shown in FIG. 6 to FIG. 9, substantially the same effect as an embodiment shown in FIG. 4 may be obtained.

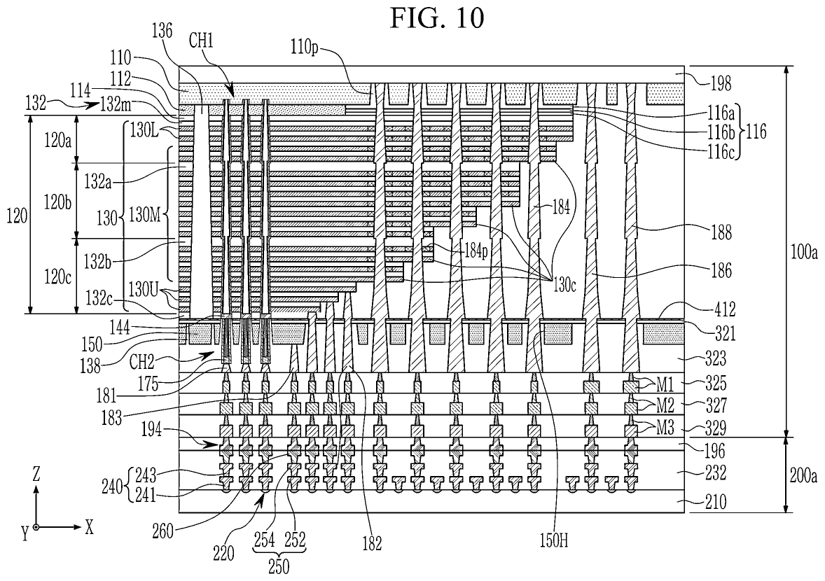

FIG. 10 is a cross-sectional view schematically showing a semiconductor device according to some embodiments.

A semiconductor device according to an embodiment shown in FIG. 10 may have a chip-to-chip (C2C) structure bonded by a wafer bonding method. That is, a lower chip including include a circuit region 200a formed on the first substrate 210 is manufactured, an upper chip including the cell region 100a formed on the second substrate 110 is manufactured, and then a semiconductor device according to an embodiment shown in FIG. 10 may be manufactured by bonding them.

The circuit region 200a may include a first bonding structure 260 connected to the first substrate 210, the circuit element 220, the lower conductive via 240, the lower wire 250, and the lower wire 250, and the circuit region 200a may be positioned on a surface facing the cell region 100a.

The cell region 100a may be connected to the second substrate 110, the gate stacking structure 120, the first and second channel structures CH1 and CH2, the selection gate electrode 150, the contact portions 182, 184, 186, and 188, and the third upper wire structure M3, and the cell region 100a may include a second bonding structure 194 positioned on a surface facing the circuit region 200a.

The second substrate 110 may be a semiconductor substrate including a semiconductor material. For example, the second substrate 110 may be a semiconductor substrate made of a semiconductor material, and may be a semiconductor substrate in which a semiconductor layer is formed on a base substrate. For example, the second substrate 110 may include monocrystalline or polycrystalline silicon, germanium, silicon-germanium, silicon-on-insulator, germanium-on-insulator, or the like.

In the gate stack structure 120, the gate electrode 130 may include the lower gate electrode 130L, the memory cell gate electrode 130M, and the upper gate electrode 130U sequentially positioned on the second substrate 110a toward the circuit region 200a from the second substrate 110a. That is, as illustrated in FIG. 10, the gate stack structure 120 may be sequentially stacked on a lower portion of the second substrate 110 in the drawing, and thus the gate stack structure 120 illustrated in FIG. 1 may be positioned in a vertically inverted manner.

Accordingly, the first to third upper wire structures M1, M2, and M3 positioned on the gate stacking structure 120 may be positioned adjacent to the circuit region 200a. A region other than the second junction structure 194 may be covered or overlapped by a junction insulating layer 196. As such, in the cell region 100a, the second bonding structure 194 may be positioned to face the circuit region 200a.

For example, the second bonding structure 194 of the cell region 100a and the first bonding structure 260 of the circuit region 200a may include aluminum (Al), copper (Cu), tungsten (W), or an alloy thereof. For example, the first and second bonding structure 260, and 194 includes copper, such that the cell region 100a and the circuit region 200a may be connected (e.g., bonded to directly contact) by copper-to-copper bonding.

In FIG. 10, the structure and the connection relationship of the contact portions 182, 184, 186, and 188 and the gate stacking structure 120 described with reference to FIG. 1 to FIG. 4 may be applied in a substantially similar manner.

The semiconductor device according to some embodiments may further include an input/output pad (not illustrated) and an input/output connecting wire (not illustrated) electrically connected thereto. The input/output connecting wire may be electrically connected to a portion of the second junction structure 194. The input/output pad may be positioned on, for example, an insulating layer 198 covering or overlapping an outer surface of the second substrate 110. According to some embodiments, a separate input/output pad electrically connected to the circuit region 200a may be provided.

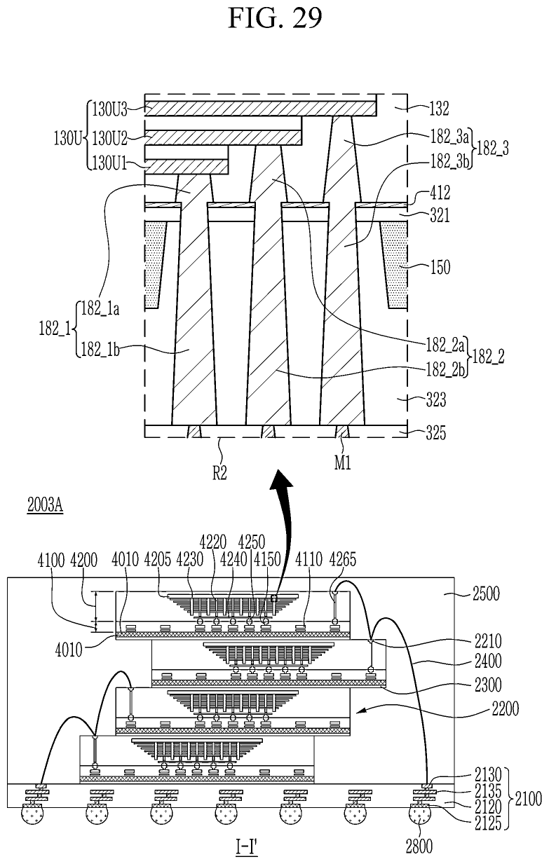

As an example, the circuit region 200a and the cell region 100a may be portions corresponding to the first structure 1100F and the second structure 1100S of the semiconductor device 1100 included in the electronic system 1000 shown in FIG. 26, respectively. Alternatively, the circuit region 200a and the cell region 100a may be regions that include a first structure 4400 and a second structure 4200 of a semiconductor chip 2200a shown in FIG. 29, respectively.

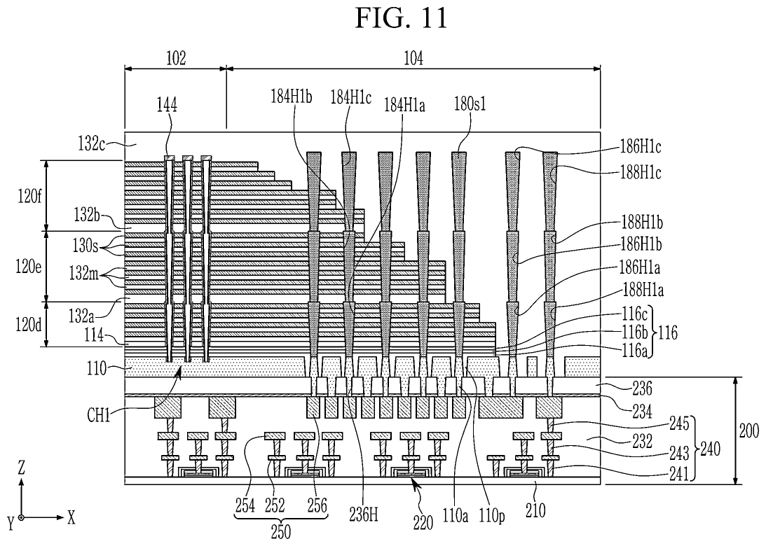

Hereinafter, referring to FIG. 11 to FIG. 25, a manufacturing method of a semiconductor device will be described. In the following embodiments, same reference numerals refer to components identical to those of the previously described embodiments, and redundant descriptions will be omitted or simplified, and description will focus on differences.

FIG. 11 to FIG. 16 are cross-sectional views for explaining a manufacturing method of a semiconductor device according to an embodiment. Specifically, FIG. 11 to FIG. 16 are cross-sectional views showing cross-sections corresponding to FIG. 1.

First, referring to FIG. 11, the second substrate 110 may be formed on the circuit region 200. The process step for forming the second substrate 110 may include forming the contact hole 236H to expose the third lower wire layer 256 of the circuit region 200 by patterning the third circuit insulation layer 236 of the circuit region 200, and then forming and patterning a substrate material layer 110a for forming the second substrate 110 on the third circuit insulation layer 236. In the step for depositing the substrate material layer 110a, the substrate material layer 110a may fill or be in the contact hole 236H of the third circuit insulation layer 236.

A partial region of the second substrate 110 connected to the substrate material layer 110a and the substrate material layer 110a may form a portion of each the through-gate contact portion 184, a portion of the source contact portion 186, and a portion of the through-contact portion 188, respectively, in a process step to be described later.

The substrate material layer 110a may include for example, polysilicon doped with impurities.

Subsequently, by patterning the substrate material layer 110a, the substrate insulation pattern 110p may be formed by filling an insulating material in a region from which a portion of the substrate material layer 110a is removed.

Subsequently, the horizontal insulation layer 116 and the second horizontal conductive layers 112 and 114 may be formed on the second substrate 110.

In more detail, the horizontal insulation layer 116 may be formed on the second substrate 110 by using the insulating material. The horizontal insulation layer 116 may be formed as a single layer or multiple layers. For example, the horizontal insulation layer 116 may include a first horizontal insulation layer 116a, a second horizontal insulation layer 116b, and a third horizontal insulation layer 116c that are sequentially stacked. For example, each of the first horizontal insulation layer 116a, the second horizontal insulation layer 116b, and the third horizontal insulation layer 116c may include silicon oxide, silicon nitride, and silicon oxide. That is, the horizontal insulation layer 116 may have a structure in which a layer made of silicon nitride is positioned between layers made of silicon oxide. At least a portion of the horizontal insulation layer 116 may be a layer to be replaced with the first horizontal conductive layer 112 in a subsequent process. That is, the horizontal insulation layer 116 may be formed to include a portion where the first horizontal conductive layer 112 is to be formed.

Subsequently, the second horizontal conductive layer 114 may be formed on the horizontal insulation layer 116. The second horizontal conductive layer 114 may be formed by using a semiconductor material (e.g., polysilicon). For example, the second horizontal conductive layer 114 may include polysilicon doped with impurities.

Subsequently, by alternately stacking a plurality of interlayer insulation layers 132m and a plurality of sacrificial insulation layers 130s on the second horizontal conductive layer 114, a first stacking structure 120d that is a lower structure body may be formed. After alternately stacking the interlayer insulation layer 132m and a sacrificial insulation layer 130s, a first gate upper insulation layer 132a may be formed in an uppermost portion.

The process step for forming the first stacking structure 120d may include performing a stepwise etching process on the sacrificial insulation layer 130s and the interlayer insulation layer 132m while sequentially increasing an exposed region by using a mask layer.

Accordingly, in the connecting region 104, extension lengths of the sacrificial insulation layer 130s and the interlayer insulation layer 132m according to a direction that is horizontal with respect to the second substrate 110 may be sequentially smaller as the distance becomes farther from the second substrate 110. That is, the stepwise etching process may be performed such that the first stacking structure 120d may have a step shape in the connecting region 104 in a cross-sectional view.

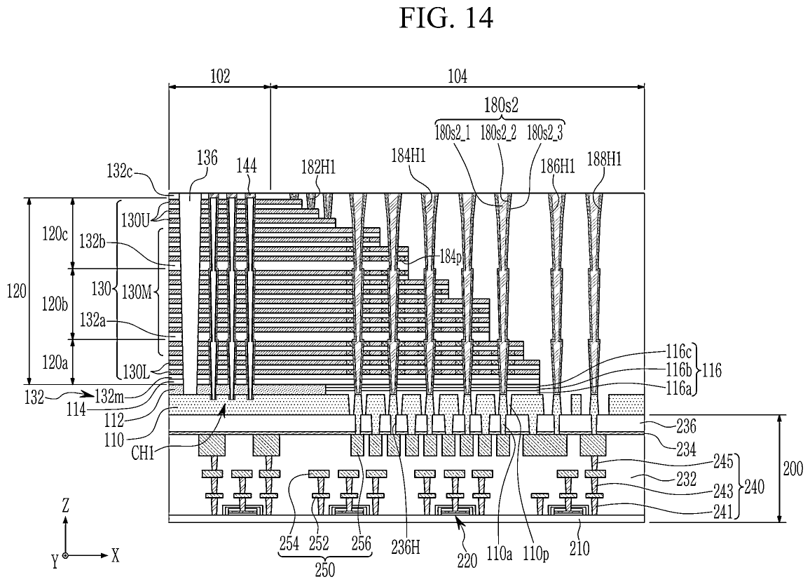

The sacrificial insulation layer 130s may be formed of a different material from the interlayer insulation layer 132m. The interlayer insulation layer 132m may include silicon oxide, silicon nitride, silicon nitride oxide, a low dielectric constant material, or the like, and the sacrificial insulation layer 130s may include at least one of silicon, silicon oxide, silicon carbide, silicon nitride, but may be made of a different material from the interlayer insulation layer 132m. For example, the interlayer insulation layer 132m may include silicon oxide, and the sacrificial insulation layer 130s may include silicon nitride. The sacrificial insulation layer 130s may be a layer to be replaced with the gate electrode 130 (refer to FIG. 14) in a subsequent process. That is, the sacrificial insulation layer 130s may be formed correspond to a portion where the gate electrode 130 (refer to FIG. 14) is to be.

Subsequently, by patterning the first stacking structure 120d, a first sub-channel hole (not shown) penetrating or extending into the first stacking structure 120d may be formed in a region corresponding to the cell array region 102, and a first sub-through gate contact hole 184H1a penetrating or extending into the first stacking structure 120d in a region corresponding to the connecting region 104 may be formed. In addition, a first sub-source contact hole 186H1a and a first sub-through contact hole 188H1a that are positioned in an outer side of the first stacking structure 120d in a region corresponding to the connecting region 104 and penetrating or extending into the first gate upper insulation layer 132a may be formed.

By the first sub-channel hole (not shown), the second horizontal conductive layer 114 and the horizontal insulation layer 116 may be penetrated, and the second substrate 110 may not be penetrated. That is, the depth of the first sub-channel hole formed in the second substrate 110 may be smaller than a thickness of the second substrate 110. The first sub-channel hole (not shown) may be formed to correspond to a region where the first channel structure CH1 (refer to FIG. 1) is formed.

By the first sub-through gate contact hole 184H1a, the second horizontal conductive layer 114 and the horizontal insulation layer 116 may be penetrated, and the second substrate 110 may not be penetrated. The first sub-through gate contact hole 184H1a may be formed on the second substrate 110 region connected to the third lower wire layer 256 through the contact hole 236H formed in the third circuit insulation layer 236 of the circuit region 200. In addition, the first sub-source contact hole 186H1a and the first sub-through contact hole 188H1a that penetrate or extend into the first gate upper insulation layer 132a may be positioned in the outer side of the first stacking structure 120d, and may be formed on the second substrate 110 region connected to the third lower wire layer 256 through the contact hole 236H formed in the third circuit insulation layer 236 of the circuit region 200. That is, the first sub-through gate contact hole 184H1a may be formed to correspond to a region where the through-gate contact portion 184 (refer to FIG. 1) is formed, and the first sub-source contact hole 186H1a and the first sub-through contact hole 188H1a may be formed to correspond to regions where the source contact portion 186 (refer to FIG. 1) and the through-contact portion 188 (refer to FIG. 1) are formed, respectively.

Subsequently, a channel sacrificial pattern (not shown) may be formed within the first sub-channel hole, and a first contact portion sacrificial pattern 180s1 may be formed in each of the first sub-through gate contact hole 184H1a, the first sub-source contact hole 186H1a, and the first sub-through contact hole 188H1a. The channel sacrificial pattern may include, for example, polysilicon, and the first contact portion sacrificial pattern 180s1 may include, for example, carbon-based material. However, the material included in the channel sacrificial pattern and the first contact portion sacrificial pattern 180s1 is not limited thereto, and may be changed in various ways.

Subsequently, by alternately stacking the plurality of interlayer insulation layers 132m and the plurality of sacrificial insulation layers 130s on the first stacking structure 120d, a second stacking structure 120e may be formed. After alternately stacking the interlayer insulation layer 132m and the sacrificial insulation layer 130s, a second gate upper insulation layer 132b may be formed in an uppermost portion. A manufacturing method or the like of the sacrificial insulation layer 130s, the interlayer insulation layer 132m, the second gate upper insulation layer 132b of the second stacking structure 120e may be substantially the same as the case of the first stacking structure 120d, and the description thereof is not included herein.

Subsequently, by patterning the second stacking structure 120e, a second sub-channel hole (not shown) penetrating or extending into the second stacking structure 120e may be formed in a region corresponding to the cell array region 102. The second sub-channel hole may be formed to overlap the first sub-channel hole. By forming the second sub-channel hole, at least a portion of the channel sacrificial pattern formed within the first sub-channel hole may be exposed.

In addition, by patterning the second stacking structure 120e, a second sub-through gate contact hole 184H1b penetrating or extending into the second stacking structure 120e and the second gate upper insulation layer 132b may be formed in a region corresponding to the connecting region 104, and a second sub-source contact hole 186H1b and a second sub-through contact hole 188H1b that are positioned in an outer side of the second stacking structure 120e in a region corresponding to the connecting region 104 and penetrate the second gate upper insulation layer 132b may be formed.

The second sub-through gate contact hole 184H1b may be formed to overlap the first sub-through gate contact hole 184H1a, and the second sub-source contact hole 186H1b and the second sub-through contact hole 188H1b may be formed to overlap the first sub-source contact hole 186H1a and the first sub-through contact hole 188H1a, respectively.

As the second sub-through gate contact hole 184H1b, the second sub-source contact hole 186H1b, and the second sub-through contact hole 188H1b are formed, each of the first sub-through gate contact hole 184H1a, at least a portion of the first contact portion sacrificial pattern 180s1 positioned in the first sub-source contact hole 186H1a, and the first sub-through contact hole 188H1a may be exposed.

Subsequently, the channel sacrificial pattern (not shown) may be formed within the second sub-channel hole, and the first contact portion sacrificial pattern 180s1 may be formed in each of the second sub-through gate contact hole 184H1b, the second sub-source contact hole 186H1b, and the second sub-through contact hole 188H1b.

Subsequently, by alternately stacking the plurality of interlayer insulation layers 132m and the plurality of sacrificial insulation layers 130s on the second stacking structure 120c, a third stacking structure 120f may be formed. After alternately stacking the interlayer insulation layer 132m and the sacrificial insulation layer 130s, the third gate upper insulation layer 132c may be formed in an uppermost portion. A manufacturing method or the like of the sacrificial insulation layer 130s, the interlayer insulation layer 132m, the third gate upper insulation layer 132c of the third stacking structure 120f may be substantially the same as the case of the second stacking structure 120e, and the description thereof is not included herein.

Subsequently, by patterning the third stacking structure 120f, a third sub-channel hole (not shown) penetrating or extending into the third stacking structure 120f may be formed in a region corresponding to the cell array region 102. The third sub-channel may be formed to overlap the second sub-channel hole. By forming the third sub-channel, at least a portion of the channel sacrificial pattern formed within the second sub-channel hole may be exposed.

In addition, by patterning the second stacking structure 120e, a third sub-through gate contact hole 184H1c penetrating or extending into the third stacking structure 120f and the third gate upper insulation layer 132c may be formed in a region corresponding to the connecting region 104. That is, a portion of the third sub-through gate contact holes 184H1c is formed to penetrate or extend into the third stacking structure 120f, and a remaining portion may be formed to penetrate or extend into the third gate upper insulation layer 132c.

A third sub-source contact hole 186H1c and a third sub-through contact hole 188H1c that are positioned in an outer side of the third stacking structure 120f in a region corresponding to the connecting region 104 and penetrating or extending into the third gate upper insulation layer 132c may be formed.

The third sub-through gate contact hole 184H1c may be formed to overlap the second sub-through gate contact hole 184H1b, and the third sub-source contact hole 186H1c and the third sub-through contact hole 188H1c may be formed to overlap the second sub-source contact hole 186H1b and the second sub-through contact hole 188H1b, respectively.

As the third sub-through gate contact hole 184H1c, the third sub-source contact hole 186H1c, and the third sub-through contact hole 188H1c are formed, at least a portion of the first contact portion sacrificial pattern 180s1 positioned in each of the second sub-through gate contact hole 184H1b, the second sub-source contact hole 186H1b, and the second sub-through contact hole 188H1b may be exposed.

Subsequently, the channel sacrificial pattern (not shown) may be formed within the third sub-channel, and the first contact portion sacrificial pattern 180s1 may be formed in each of the third sub-through gate contact hole 184H1c, the third sub-source contact hole 186H1c, and the third sub-through contact hole 188H1c.

Each of the first to third sub-through gate contact holes 184H1a, 184H1b, and 184H1c may have a shape of which the width gradually narrows from an upper portion to a lower portion. For example, a width of an upper portion of the first sub-through gate contact hole 184H1a may be larger than a width of a lower portion of the second sub-through gate contact hole 184H1b, and a width of an upper portion of the second sub-through gate contact hole 184H1b may be larger than a width of a lower portion of the third sub-through gate contact hole 184H1c.

Accordingly, the widths of the first to third sub-through gate contact holes 184H1a, 184H1b, and 184H1c overlapping each other may have a form of which the width gradually decreases from the uppermost portion, then increases, and then gradually decreases again. That is, may include a bent portion or step difference (e.g., a step portion) in a boundary portion of each of the first to third sub-through gate contact holes 184H1a, 184H1b, and 184H1c.

The contents with respect to the relationship of widths of the first to third sub-through gate contact holes 184H1a, 184H1b, and 184H1c may also be substantially equally applied to the relationship of widths of the first to third sub-channel holes (not shown), the relationship of widths of the first to third sub-source contact holes 186H1a, 186H1b, and 186H1c, the relationship of widths of the first to third sub-through contact holes 188H1a, 188H1b, and 188H1c, and as such, the description with respect to is not included herein.

Subsequently, the first channel structure CH1 may be formed in a hole formed by removing the channel sacrificial pattern (not shown) positioned within the first to third sub-channel holes (not shown) in a region corresponding to the cell array region 102. For example, the first gate dielectric layer 146 (refer to FIG. 2), the first channel layer 140 (refer to FIG. 2), the first core insulation layer 142 (refer to FIG. 2) may be sequentially formed to fill or be in the hole formed by removing the channel sacrificial pattern, and by forming the first channel pad 144 (refer to FIG. 2) that covers or overlaps the first gate dielectric layer 146, the first channel layer 140, the first core insulation layer 142, and the first channel structure CH1 may be formed.

Subsequently, a portion of the third upper gate insulation layer 132c may be additionally formed on the first channel structure CH1 and a first contact portion sacrificial pattern 181s1. Accordingly, the third upper gate insulation layer 132c may cover or overlap the first channel structure CH1 and the first contact portion sacrificial pattern 181s1, and a thickness of the third upper gate insulation layer 132c may be thicker than a thickness of first and second upper gate insulation layers 132a and 132b. However, the present disclosure is not limited thereto, and in some embodiments, an insulation layer including a different material from the third upper gate insulation layer 132c may be formed on the first channel structure CH1 and the first contact portion sacrificial pattern 181s1. As such, when an insulation layer including a different material from the third upper gate insulation layer 132c is formed, an interface may be provided at a boundary portion to the third upper gate insulation layer 132c.

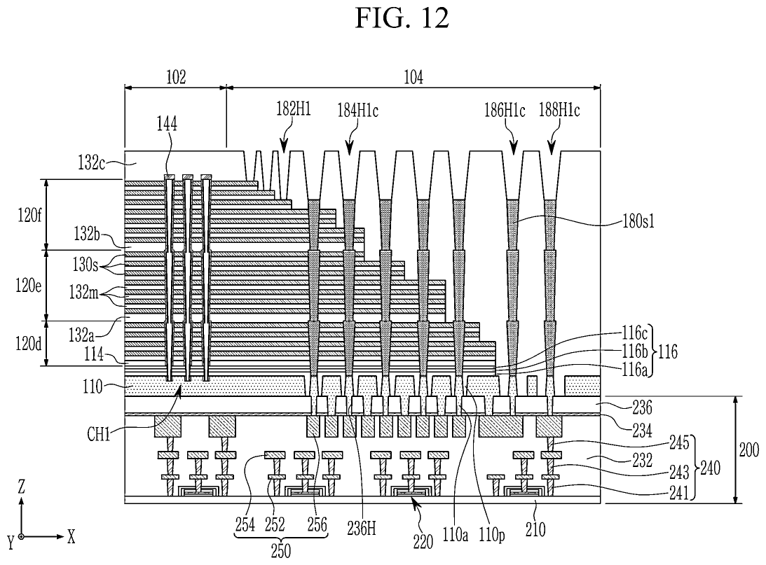

Subsequently, referring to FIG. 12, in a region corresponding to the connecting region 104, by patterning the third upper gate insulation layer 132c, first gate contact portion holes 182H1 may be formed. The first gate contact portion hole 182H1 may expose at least a portion of the sacrificial insulation layer 130s constituting the third stacking structure 120f. For example, the first gate contact portion hole 182H1 may be formed between the first channel structure CH1 and the third sub-through gate contact hole 184H1c, and the first gate contact portion hole 182H1 may expose the sacrificial insulation layers 130s positioned between the first channel structure CH1 and the third sub-through gate contact hole 184H1c. That is, the first gate contact portion hole 182H1 may sequentially expose a portion of the sacrificial insulation layer 130s positioned in an uppermost portion of the third stacking structure 120f.

Accordingly, each of the first gate contact portion holes 182H1 may have a different depth. For example, a depth of each of the first gate contact portion holes 182H1 may be formed to be deeper as approaches the third sub-through gate contact hole 184H1c.

In the process step for patterning the third upper gate insulation layer 132c in order to form the first gate contact portion holes 182H1, the third upper gate insulation layer 132c positioned on the first contact portion sacrificial pattern 180s1 and the first contact portion sacrificial pattern 180s1 positioned in the third sub-through gate contact hole 184H1c, the third sub-source contact hole 186H1c, and the third sub-through contact hole 188H1c may be removed together.

An upper surface of the first contact portion sacrificial pattern 180s1 remaining within the third sub-through gate contact hole 184H1c, the third sub-source contact hole 186H1c, and the third sub-through contact hole 188H1c may be positioned at substantially the same level as a bottom surface of the first gate contact portion hole 182H1 having a deepest or greatest depth among the first gate contact portion holes 182H1. However, the present disclosure is not limited thereto, and the level of the upper surface of the first contact portion sacrificial pattern 180s1 remaining within the third sub-through gate contact hole 184H1c, the third sub-source contact hole 186H1c, and the third sub-through contact hole 188H1c may be changed in various ways.

In the process step for patterning the third upper gate insulation layer 132c in order to form the first gate contact portion holes 182H1, by removing the third upper gate insulation layer 132c forming an inner side surface of the third sub-through gate contact hole 184H1c together with the first contact portion sacrificial pattern 180s 1 filling or in the third sub-through gate contact hole 184H1c, a width of an upper region of the third sub-through gate contact hole 184H1c may be expanded. Accordingly, an inclination of an inner side surface of the upper region of the third sub-through gate contact hole 184H1c may become different from an inclination of a remaining region of the third sub-through gate contact hole 184H1c. For example, an inclination of an inner side surface of the region where the first contact portion sacrificial pattern 180s1 among the third sub-through gate contact hole 184H1c remains may be steeper than an inclination of an inner side surface of a region from which the first contact portion sacrificial pattern 180s1 is removed.

Since the third sub-through gate contact hole 184H1c, the first contact portion sacrificial pattern 180s1 positioned within the third sub-source contact hole 186H1c, and the third sub-through contact hole 184H1c may be removed together in the same process step, the description with respect to the inner side surface inclination of the third sub-through gate contact hole 184H1c may be equally applied to the third sub-source contact hole 186H1c and the third sub-through contact hole 188H1c, and contents related thereto is not included herein.

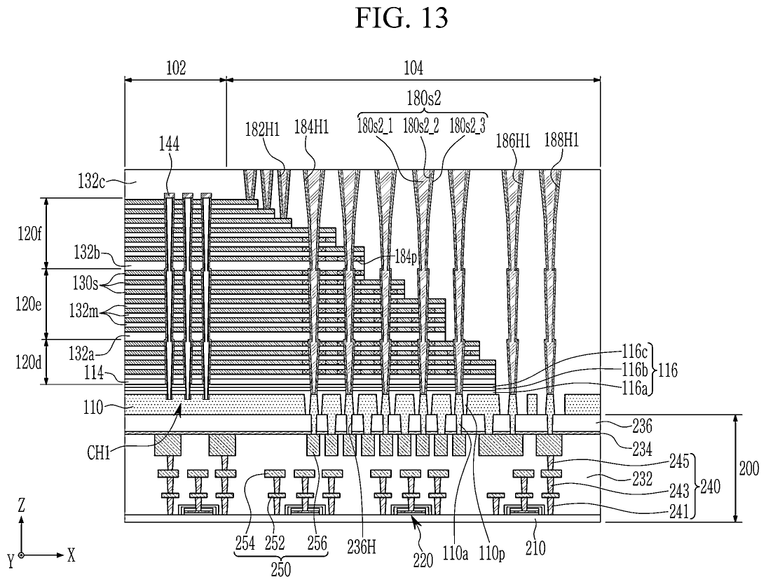

Subsequently, and referring to FIG. 13, and the first to third sub-through contact holes 186H1a, 186H1b, and 186H1c (refer to FIG. 11), the first through-gate contact hole 184H1, the first source contact hole 186H1, and the first through-contact hole 188H1 that penetrate or extend into the first to third stacking structures 120d, 120c, and 120f may be formed by removing the first contact portion sacrificial patterns 180s1 positioned within the first to third sub-through gate contact holes 184H1a, 184H1b, and 184H1c (refer to FIG. 11), the first to third sub-source contact holes 186H1a, 186H1b, and 186H1c (refer to FIG. 11). The first through-gate contact hole 184H1, the first source contact hole 186H1, and the first through-contact hole 188H1 that penetrate or extend into the first to third stacking structures 120d, 120e, and 120f may penetrate or extend into the horizontal insulation layer 116 and extend to the second substrate 110.

Subsequently, the gate insulation pattern 184p may be formed through the first through-gate contact hole 184H1.

In more detail, when an etching material is introduced through the first through-gate contact hole 184H1, as the sacrificial insulation layer 130s of a portion adjacent to the first through-gate contact hole 184H1 may be etched in the horizontal direction, a tunnel portion may be formed.

The tunnel portion may be formed to have a relatively short length in a region corresponding to the pad portion WP (refer to FIG. 5) of the connection gate electrode 130c, and may be formed to have a relatively long length in a region corresponding to the remaining gate electrode 130r (refer to FIG. 5). To this end, in some embodiments, after forming the tunnel portion, the sacrificial insulation layer may be additionally formed within the first through-gate contact hole 184H1 and the tunnel portion.

Subsequently, a preliminary insulation layer for forming the gate insulation pattern 184p may be filled or positioned in the tunnel portion and the first through-gate contact hole 184H1.

The preliminary insulation layer may be a layer of which a part remains to form the gate insulation pattern 184p. The preliminary insulation layer may include a first preliminary insulation layer and a second preliminary insulation layer sequentially formed within the tunnel portion. For example, the first preliminary insulation layer may include silicon nitride oxide, and the second preliminary insulation layer may include silicon oxide.

In the process step for forming the gate insulation pattern 184p, an oxidation treatment process may be performed on the first preliminary insulation layer. In the first preliminary insulation layer, a portion adjacent to the first through-gate contact hole 184H1 may be changed to a silicon oxide layer by being oxidized, and a portion far from the first through-gate contact hole 184H1 may remain as a silicon nitride oxide layer by not being oxidized.

The preliminary insulation layer may not fully fill or be in the tunnel portion formed in a portion corresponding to the pad portion WP (refer to FIG. 5) of the connection gate electrode 130c (refer to FIG. 5) having a relatively large thickness, and may be formed to fill or be in the tunnel portion formed in a portion corresponding to the remaining gate electrode 130r (refer to FIG. 5). This may be due to the relative thickness difference.

Subsequently, a second contact portion sacrificial pattern 180s2 may be formed within the first gate contact portion hole 182H1, the first through-gate contact hole 184H1, the first source contact hole 186H1, and the first through-contact hole 188H1.

The second contact portion sacrificial pattern 180s2 may be formed in a single layer or multiple layers. For example, the second contact portion sacrificial pattern 180s2 may include a first contact portion sacrificial layer 180s2_1, a second contact portion sacrificial layer 180s2_2, and a third contact portion sacrificial layer 180s2_3.

The first contact portion sacrificial layer 180s2_1 may be at least partially surrounded by the second contact portion sacrificial layer 180s2_2. The second contact portion sacrificial layer 180s2_2 may be formed to at least partially surround a bottom surface and a side surface of the first contact portion sacrificial layer 180s2_1. The third contact portion sacrificial layer 180s2_3 may be positioned on the second contact portion sacrificial layer 180s2_2. That is, it may be conformally formed along a side surface of the third contact portion sacrificial layer 180s2_3. In other words, the second contact portion sacrificial layer 180s2_2 may be positioned between the first contact portion sacrificial layer 180s2_1 and the third contact portion sacrificial layer 180s2_3.

The first contact portion sacrificial layer 180s2_1, the second contact portion sacrificial layer 180s2_2, and the third contact portion sacrificial layer 180s2_3 may include different materials. For example, the first contact portion sacrificial layer 180s2_1 may include polysilicon, and the second contact portion sacrificial layer 180s2_2 may include silicon nitride, and the third contact portion sacrificial layer 180s2_3 may include silicon oxide. However, this is merely an example, and the material included in the first contact portion sacrificial layer 180s2_1, the second contact portion sacrificial layer 180s2_2, and the third contact portion sacrificial layer 180s2_3 may be changed in various ways.

Subsequently, and referring to FIG. 14, the gate stacking structure 120 may be formed by replacing the sacrificial insulation layer 130s with the gate electrode 130.

First, an opening may be formed in a region corresponding to the separation structure 136 (refer to FIG. 1) so as to penetrate or extend into the first to third gate stacking structures 120a, 120b, and 120c. By the opening, side surfaces of respective layers forming the first to third gate stacking structures 120a, 120b, and 120c may be exposed.

The opening may be formed to penetrate or extend into all layers constituting the first to third gate stacking structures 120a, 120b, and 120c. In addition, the opening may penetrate or extend into the second horizontal conductive layer 114 and the horizontal insulation layer 116. By the opening, gate stacking structures 120 adjacent to each other may be separated.

Subsequently, the horizontal insulation layer 116 may be removed through the opening, and the first horizontal conductive layer 112 may be formed within a space from which the horizontal insulation layer 116 is removed. The first horizontal conductive layer 112 may be positioned between the second substrate 110 and the second horizontal conductive layer 114. The first horizontal conductive layer 112 may include polysilicon doped with impurities. The first horizontal conductive layer 112 may function as a common source line together with the second substrate 110 and the second horizontal conductive layer 114.

Subsequently, by selectively removing the sacrificial insulation layer 130s by the etching process (e.g., wet etching process) through the opening, the gate stacking structure 120 including the first to third gate stacking structures 120a, 120b, and 120c may be formed.

In more detail, first, the sacrificial insulation layer 130s may be removed, and the gate electrode 130 may be formed within a space from which the sacrificial insulation layer 130s is removed. That is, after removing the sacrificial insulating layer 130s using an etching process, a metal material such as tungsten (W), copper (Cu), or aluminum (Al) may be deposited to form the gate electrode 130. The gate electrode 130 may include the lower gate electrode 130L, the memory cell gate electrode 130M, the upper gate electrode 130U sequentially positioned on the second substrate 110.

Subsequently, a planarization process may be performed such that the first channel pad 144 may be exposed. The planarization process step may be performed by, for example, chemical mechanical polishing (CMP). However, the planarization process method is not limited thereto, and may be changed in various ways.

In the planarization process step, a portion of the second contact portion sacrificial pattern 180s2 filling a portion of the third upper gate insulation layer 132c, a portion of the separation structure 136, and the first gate contact portion hole 182H1, the first through-gate contact hole 184H1, the first source contact hole 186H1, and the first through-contact hole 188H1 may be removed together. By performing the planarization process, an upper surface of the third upper gate insulation layer 132c, an upper surface of the separation structure 136, and an upper surface of the second contact portion sacrificial pattern 180s2 may be substantially planarized.

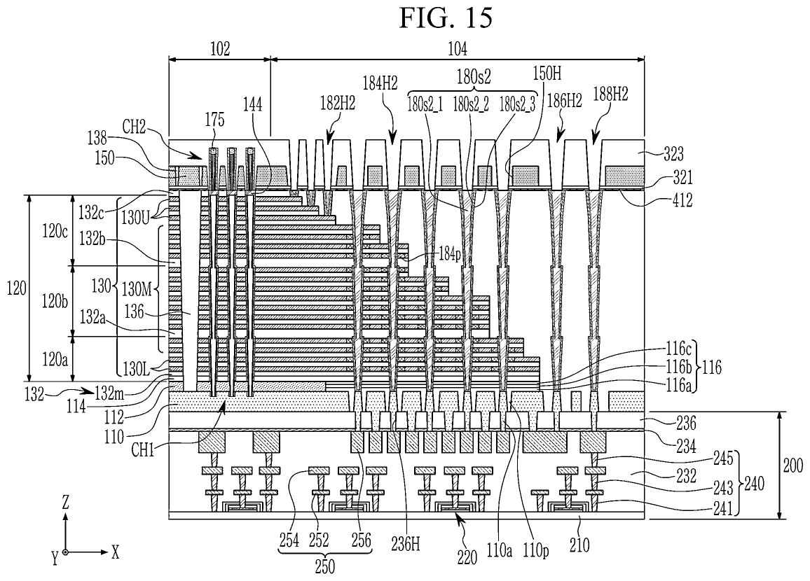

Subsequently, and referring to FIG. 15, the first upper insulation layer 412 and the second upper insulation layer 321 may be sequentially formed on the gate stacking structure 120. The first upper insulation layer 412 may cover or overlap the first channel pad 144, the upper surface of the third upper gate insulation layer 132c, the upper surface of the separation structure 136, and the upper surface of the second contact portion sacrificial pattern 180s2. The second upper insulation layer 321 may cover or overlap the first upper insulation layer 412. The second upper insulation layer 321 may be formed to have a thicker thickness than the first upper insulation layer 412.

The first upper insulation layer 412 and the second upper insulation layer 321 may include different materials. That is, the first upper insulation layer 412 may include a material having etching selectivity with respect to the second upper insulation layer 321. The first upper insulation layer 412 may serve as an etch stop layer in a subsequent etching process step. For example, the first upper insulation layer 412 may include silicon nitride, and the second upper insulation layer 321 may include silicon oxide. However, the material included in the first upper insulation layer 412 and the second upper insulation layer 321 is not limited thereto, and may be changed in various ways.

Subsequently, the selection gate electrode 150 may be formed on the second upper insulation layer 321. The selection gate electrode 150 may be formed to have a thicker or greater thickness than the gate electrode 130. The selection gate electrode 150 may include a different material from the gate electrodes 130. For example, the selection gate electrode 150 may include a semiconductor material such as polysilicon.

Subsequently, by patterning the selection gate electrode 150, the plurality of selection gate holes 150H penetrating or extending into the selection gate electrode 150 may be formed. The selection gate hole 150H may expose the second upper insulation layer 321. In addition, the plurality of selection gate holes 150H that penetrate or extend into the selection gate electrode 150 may have different widths.

Subsequently, the third upper insulation layer 323 may be formed on the selection gate electrode 150. The third upper insulation layer 323 may fill or be in the selection gate hole 150H, and may cover or overlap the selection gate electrode 150.

By forming an insulating material in the selection gate hole 150H positioned in a region corresponding to the cell array region 102, the upper separation structure 138 may be formed. For example, the insulating material that fills or is in the selection gate hole 150H may be the third upper insulation layer 323.

Subsequently, in a region corresponding to the cell array region 102, by patterning the third upper insulation layer 323, a second channel hole (not shown) may be formed in a region corresponding to the second channel structure CH2. The second channel hole may sequentially penetrate or extend into the third upper insulation layer 323, the second upper insulation layer 321, and the first upper insulation layer 412, and expose the first channel pad 144.

Subsequently, the second channel structure CH2 may be formed within the second channel hole. For example, the second gate dielectric layer 168 (refer to FIG. 3), the semiconductor spacer layer 166 (refer to FIG. 3), the second channel layer 164 (refer to FIG. 3), the second core insulation layer 162 (refer to FIG. 3) are sequentially formed to fill or be in the second channel hole, a portion of the second core insulation layer 162, the second channel layer 164, and the semiconductor spacer layer 166 are removed, and then, the second channel pad 175 that covers or overlaps the second core insulation layer 162, the second channel layer 164, and the semiconductor spacer layer 166 are formed to form the second channel structure CH2.

Subsequently, before forming a second gate contact portion hole 182H2, a second through-gate contact hole 184H2, a second source contact hole 186H2, and a second through-contact hole 188H2, the third upper insulation layer 323 that entirely covers or overlaps the second channel structure CH2 may be additionally formed. Accordingly, the third upper insulation layer 323 may cover or overlap the second channel pad 175.

Subsequently, in a region corresponding to the connecting region 104, the second gate contact portion hole 182H2, the second through-gate contact hole 184H2, the second source contact hole 186H2, and the second through-contact hole 188H2 may be formed by patterning the third upper insulation layer 323.

Each of the second gate contact portion hole 182H2, the second through-gate contact hole 184H2, the second source contact hole 186H2, and the second through-contact hole 188H2 may sequentially penetrate or extend into the third upper insulation layer 323 filling the selection gate hole 150H, the second upper insulation layer 321 positioned thereunder, and the first upper insulation layer 412, and may expose the second contact portion sacrificial pattern 180s2.

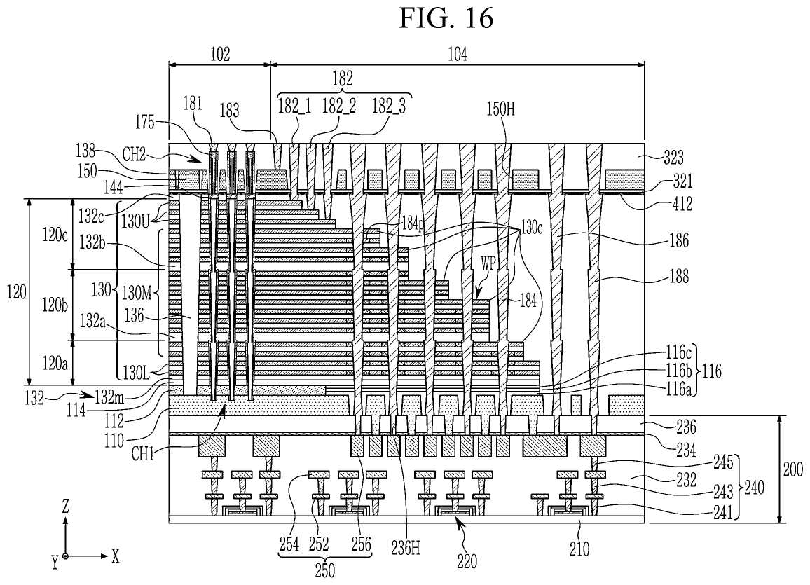

Subsequently, and referring to FIG. 16, the second contact portion sacrificial patterns 180s2 filled in each of the first gate contact portion hole 182H1 (refer to FIG. 14), the first through-gate contact hole 184H1 (refer to FIG. 14), the first source contact hole 186H1 (refer to FIG. 14), and the first through-contact hole 188H1 (refer to FIG. 14) through the second gate contact portion hole 182H2, the second through-gate contact hole 184H2, the second source contact hole 186H2, and the second through-contact hole 188H2 may be selectively removed.

In more detail, after sequentially removing the first contact portion sacrificial layer 180s2_1, the second contact portion sacrificial layer 180s2_2, and the third contact portion sacrificial layer 180s2_3 formed within the first gate contact portion hole 182H1, and by burying a conductive material such as tungsten (W), copper (Cu), aluminum (Al), or the like within the first and second gate contact portion holes 182H1 and 182H2, the upper gate contact portion 182 sequentially connected to the upper gate electrode 130U and having the structure and shape shown in FIG. 4 may be formed.

After sequentially removing the first contact portion sacrificial layer 180s2_1, the second contact portion sacrificial layer 180s2_2, and the third contact portion sacrificial layer 180s2_3 formed within the first through-gate contact hole 184H1, and by burying a conductive material such as tungsten (W), copper (Cu), aluminum (Al), or the like within the first and second through-gate contact holes 184H1 and 184H2, the through-gate contact portion 184 that is connected to the connection gate electrode 130c including the pad portion WP and insulated from the remaining gate electrode 130r (refer to FIG. 5) interposing or extending into the gate insulation pattern 184p may be formed.

In the process step for removing the second contact portion sacrificial pattern 180s2 formed within the first through-gate contact hole 184H1, a portion of the second substrate 110 contacting a bottom surface the first through-gate contact hole 184H1 together with the substrate material layer 110a positioned within the contact hole 236H exposing the third lower wire layer 256 may be removed.

For example, after removing the first contact portion sacrificial layer 180s2_1 among the second contact portion sacrificial pattern 180s2 formed within the first through-gate contact hole 184H1 (refer to FIG. 14), the second contact portion sacrificial layer 180s2_2 and the third contact portion sacrificial layer 180s2_3 formed on bottom surface of the first through-gate contact hole 184H1 are removed such that the second substrate 110 region contacting the first through-gate contact hole 184H1 may be exposed.

Subsequently, the portion of the exposed second substrate 110 may be removed. In the process step for removing the portion of the second substrate 110, the substrate material layer 110a positioned within the contact hole 236H may also be removed. Accordingly, the third lower wire layer 256 positioned in the circuit region 200 may be exposed.

Subsequently, after sequentially removing the second contact portion sacrificial layer 180s2_2 and the third contact portion sacrificial layer 180s2_3 formed on an inner side surface of the first through-gate contact hole 184H1, a conductive material such as tungsten (W), copper (Cu), aluminum (Al), or the like may be buried into the first and second through-gate contact holes 184H1 and 184H2, a region from which the portion of the second substrate 110 is removed, and a region from which the substrate material layer 110a is removed, such that the through-gate contact portion 184 connected to the third lower wire layer 256 positioned at an uppermost end of the circuit region 200 may be formed. However, the method of forming the through-gate contact portion 184 is not limited thereto, and may be changed in various ways. For example, the sequence of the process step for removing the second contact portion sacrificial pattern 180s2 formed within the first through-gate contact hole 184H1, the method of forming the through-gate contact portion 184 (refer to FIG. 16) that penetrates or extends into the second substrate 110 to be connected to the circuit region 200, or the like may be changed in various ways.

The through-gate contact portion 184 among a plurality of contact portions 184, 186, and 188 connected to the circuit region 200 was described as an example of the process step, but the contents may be substantially equally applied to the process step for forming the source contact portion 186 and the through-contact portion 188 connected to the circuit region 200.

Subsequently, and referring back to FIG. 16, the first contact electrode 181 that penetrates or extends into the third upper insulation layer 323 and is connected to the second channel pad 175, and the second contact electrode 183 that penetrates or extends into the third upper insulation layer 323 to be connected to the selection gate electrode 150 may be formed. The first and second contact electrodes 181 and 183 may include a conductive material such as tungsten (W), copper (Cu), aluminum (Al), or the like.

Subsequently, and referring to FIG. 1, the fourth to sixth upper insulation layers 325, 327, and 329 may be sequentially formed on the first and second contact electrodes 181 and 183 and the contact portions 182, 184, 186, and 188.

The fourth to sixth upper insulation layers 325, 327, and 329 may include, for example, at least one of silicon oxide, silicon nitride, and silicon nitride oxide. However, the materials are not limited thereto, and the material included in and the fourth to sixth upper insulation layers 325, 327, and 329 may be changed in various ways.

Subsequently, the first to third upper wire structures M1, M2, and M3 may be formed within the fourth to sixth upper insulation layers 325, 327, and 329, respectively. The first to third upper wire structures M1, M2, and M3 may include a conductive material such as tungsten (W), copper (Cu), aluminum (Al), or the like.

According to a manufacturing method of a semiconductor device according to an embodiment, since the gate stacking structure 120 and the upper gate contact portion 182 connected to the upper gate electrode 130U and/or the contact portions 184, 186, and 188 that penetrate or extend into the cell insulation layer 132 are formed by the same process step, the process may be simplified compared to the case of performing a separate process in order to form the gate contact portion 182, and accordingly, productivity of the semiconductor device may be improved.

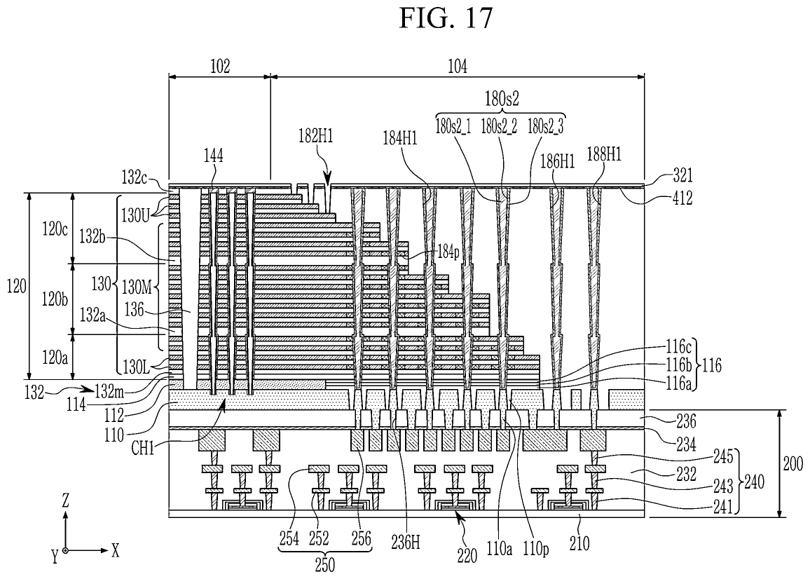

Hereinafter, referring to FIG. 17 to FIG. 25, a manufacturing method of a semiconductor device according to various embodiment will be described. In the following embodiments, same reference numerals refer to components identical to those of the previously described embodiments, and redundant descriptions will be omitted or simplified, and description will focus on differences.

FIG. 17 to FIG. 25 are cross-sectional views for explaining a manufacturing method of a semiconductor device according to some embodiments. Specifically, FIG. 17 to FIG. 25 are cross-sectional views showing cross-sections corresponding to FIG. 1.

Hereinafter, the description of the method of forming the upper gate contact portion 182 connected to the upper gate electrode 130U will be focused, and the description with respect to the process step described above with reference to FIG. 11 to FIG. 16 is not included herein.

A manufacturing method of a semiconductor device according to an embodiment shown in FIG. 17 to FIG. 20 are drawings showing a method of forming the upper gate contact portion 182 according to an embodiment shown in FIG. 7.

First, and referring to FIG. 17, the second contact portion sacrificial pattern 180s2 is formed within the first through-gate contact hole 184H1, the first source contact hole 186H1, and the first through-contact hole 188H1, and then the first upper insulation layer 412 and the second upper insulation layer 321 may be sequentially formed on the gate stacking structure 120.

The first upper insulation layer 412 may cover or overlap the first channel pad 144, the upper surface of the third upper gate insulation layer 132c, the upper surface of the separation structure 136, and the upper surface of the second contact portion sacrificial pattern 180s2.

Subsequently, the first gate contact portion hole 182H1 sequentially exposing the upper gate electrode 130U may be formed in a region corresponding to the connecting region 104. According to the present embodiment, unlike an embodiment shown in FIG. 12 and FIG. 13 in which the first gate contact portion hole 182H1 is formed before forming the second contact portion sacrificial pattern 180s2 within the first through-gate contact hole 184H1, the first source contact hole 186H1, and the first through-contact hole 188H1, the second contact portion sacrificial pattern 180s2 is formed within the first through-gate contact hole 184H1, the first source contact hole 186H1, and the first through-contact hole 188H1, and then the first gate contact portion hole 182H1 is formed.

Accordingly, in the present embodiment, unlike what was described above with reference to FIG. 12, in the process of forming the first gate contact portion hole 182H1, a width of the upper region of the third sub-through gate contact hole 184H1c is not expanded, and therefore, an upper region of the first through-gate contact hole 184H1 may not include a portion where the inclination or slope of the inner side surface changes. That is, in the present embodiment, an inner side surface of the upper region of the first through-gate contact hole 184H1 may have a continuous inclination or slope.

As opposed to penetrating or extending into the third upper gate insulation layer 132c and exposing the upper gate electrode 130U, the first gate contact portion hole 182H1 according to the present embodiment may sequentially penetrate or extend into the second upper insulation layer 321, the first upper insulation layer 412, and the third upper gate insulation layer 132c and may expose the upper gate electrode 130U.

The first gate contact portion hole 182H1 according to the present embodiment may be a region where the first portions 182_1a, 182_2a, and 182_3a of the upper gate contact portion 182 according to an embodiment shown in FIG. 7 are formed.

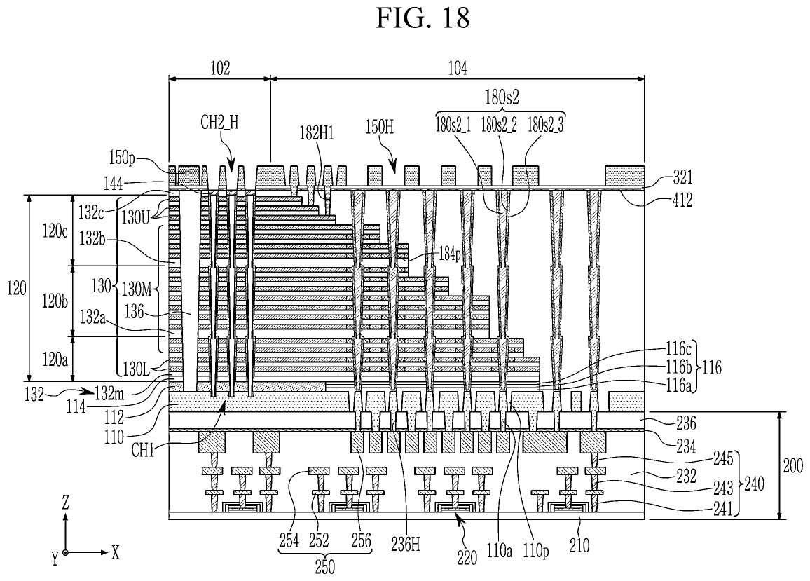

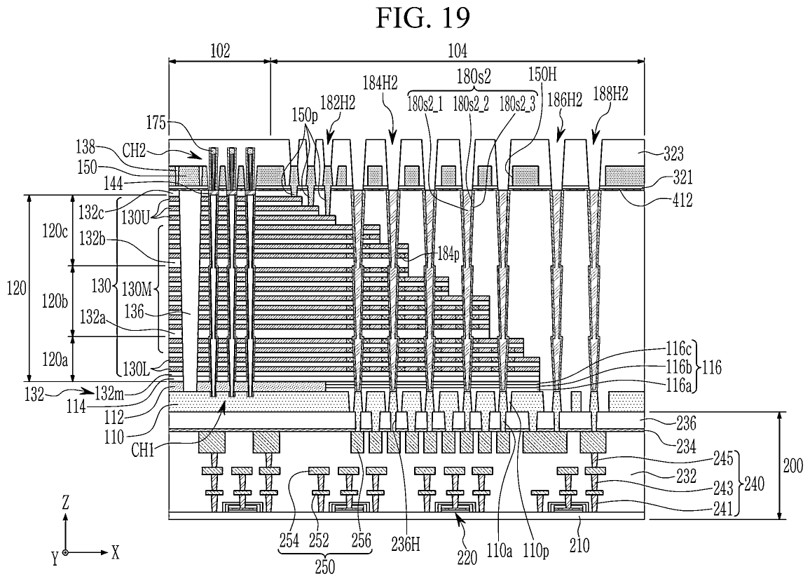

Subsequently, and referring to FIG. 18, a selection gate material layer 150p for forming the selection gate electrode 150 (refer to FIG. 19) on the second upper insulation layer 321 may be formed. The selection gate material layer 150p may include, for example, polysilicon.

The selection gate material layer 150p may fill or be in the first gate contact portion hole 182H1.

Subsequently, by patterning the selection gate material layer 150p, the plurality of selection gate holes 150H penetrating or extending into the selection gate material layer 150p may be formed. The selection gate material layer 150p may be patterned, and the remaining selection gate material layer 150p may form the selection gate electrode 150.

In the process of patterning the selection gate electrode 150, a second channel hole CH2_H may be formed in a region corresponding to the second channel structure CH2 positioned in the cell array region 102. The second channel hole CH2_H may sequentially penetrate or extend into the second upper insulation layer 321 and the first upper insulation layer 412, and expose the first channel pad 144. However, this is a merely an example, and the second channel hole CH2_H may be formed by a separate process from the selection gate hole 150H.

Subsequently, and referring to FIG. 19, the third upper insulation layer 323 may be formed on the selection gate electrode 150. The third upper insulation layer 323 may fill or be in the second channel hole CH2_H and the selection gate hole 150H, and may cover or overlap the selection gate electrode 150.

Subsequently, by patterning the third upper insulation layer 323, a through-hole may be formed in a region corresponding to the second channel structure CH2. The through-hole may penetrate or extend into the third upper insulation layer 323 that fills or is in the second channel hole CH2_H, and expose the first channel pad 144.

Subsequently, the second channel structure CH2 is formed within the through-hole, an insulating material is formed in the selection gate hole 150H positioned in a region corresponding to the cell array region 102, and thereby, the upper separation structure 138 may be formed.

Subsequently, before forming the second gate contact portion hole 182H2, the second through-gate contact hole 184H2, the second source contact hole 186H2, and the second through-contact hole 188H2, the third upper insulation layer 323 that entirely covers or overlaps the second channel structure CH2 may be additionally formed. Accordingly, the third upper insulation layer 323 may cover or overlap the second channel pad 175.

Subsequently, in a region corresponding to the connecting region 104, the second gate contact portion hole 182H2, the second through-gate contact hole 184H2, the second source contact hole 186H2, and the second through-contact hole 188H2 may be formed by patterning the third upper insulation layer 323.

The second gate contact portion hole 182H2 may expose a portion of the selection gate electrode 150 connected to the selection gate material layer 150p that fills or is in the first gate contact portion hole 182H1 (refer to FIG. 18). A portion of the selection gate electrode 150 positioned between the second gate contact portion hole 182H2 and the selection gate material layer 150p filling or in the first gate contact portion hole 182H1 may be a region where the second portions 182_1b, 182_2b, and 182_3b of the upper gate contact portion 182 according to an embodiment shown in FIG. 7 are formed, and the second gate contact portion hole 182H2 may be a region where the third portions 182_1c, 182_2c, and 182_3c of the upper gate contact portion 182 are formed.

Each of the second through-gate contact hole 184H2, the second source contact hole 186H2, and the second through-contact hole 188H2 may sequentially penetrate or extend into the third upper insulation layer 323 filling or in the selection gate hole 150H, the second upper insulation layer 321 positioned thereunder, and the first upper insulation layer 412, and may expose the second contact portion sacrificial pattern 180s2.

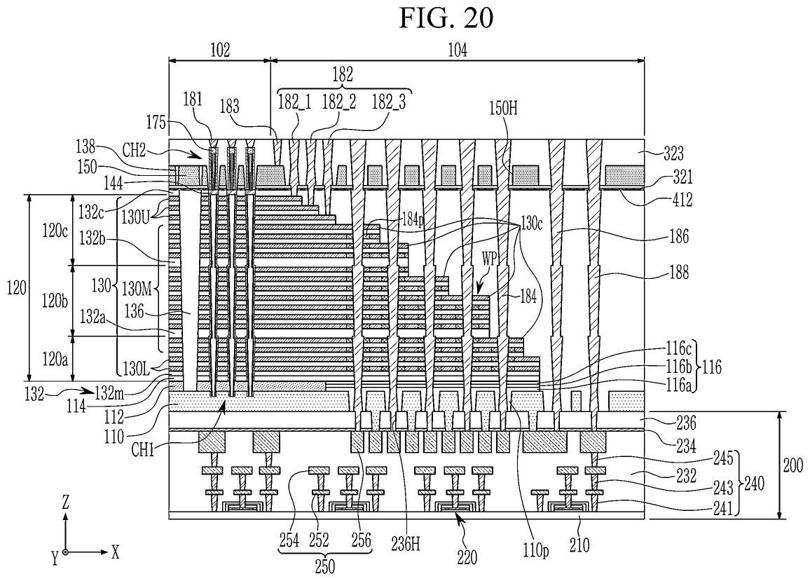

Subsequently, referring to FIG. 20, a portion of the selection gate electrode 150 connected to the selection gate material layer 150p filling or in the first gate contact portion hole 182H1 (refer to FIG. 18) through the second gate contact portion hole 182H2 may be removed. In the process step for removing a portion of the selection gate electrode 150, the selection gate material layer 150p filling or in the first gate contact portion hole 182H1 may be removed together, and accordingly, the upper gate electrode 130U may be sequentially exposed.

Subsequently, a conductive material such as tungsten (W), copper (Cu), aluminum (Al), or the like may be buried in the second gate contact portion hole 182H2 (refer to FIG. 19), a region from which a portion of the selection gate electrode 150 is removed, and a region from which the selection gate material layer 150p is removed so as to be sequentially connected to the upper gate electrode 130U, and the upper gate contact portion 182 having the structure and shape shown in FIG. 7 may be formed.

The through-gate contact portion 184, the source contact portion 186, and the through-contact portion 188 may be formed by substantially the same method as the above-described method, and the description thereof not included herein.

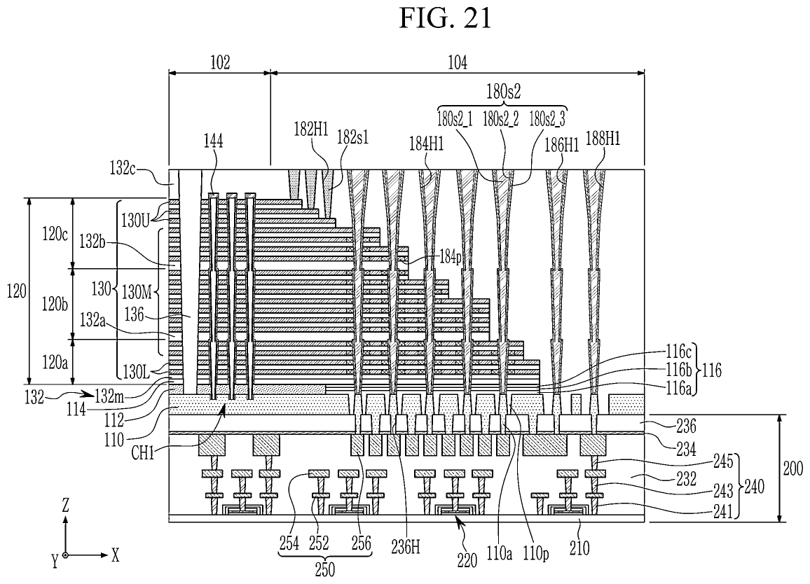

A manufacturing method of a semiconductor device according to an embodiment shown in FIG. 21 to FIG. 25 are drawings showing a method of forming the upper gate contact portion 182 according to an embodiment shown in FIG. 9.

First, referring to FIG. 21, and unlike an embodiment shown in FIG. 14, a gate contact portion sacrificial pattern 182s1 having a different structure from the second contact portion sacrificial pattern 180s2 formed in the first gate contact portion hole 182H1 within the first through-gate contact hole 184H1, the first source contact hole 186H1, and the first through-contact hole 188H1, and including a different material may be formed.

The gate contact portion sacrificial pattern 182s1 may include, for example, polysilicon. However, the material is not limited thereto, and in some embodiments, the gate contact portion sacrificial pattern 182s1 may include substantially the same structure and the same material as the second contact portion sacrificial pattern 180s2.

The first gate contact portion hole 182H1 according to the present embodiment may be a region where the first portions 182_1a, 182_2a, and 182_3a of the upper gate contact portion 182 according to an embodiment shown in FIG. 9 are formed.

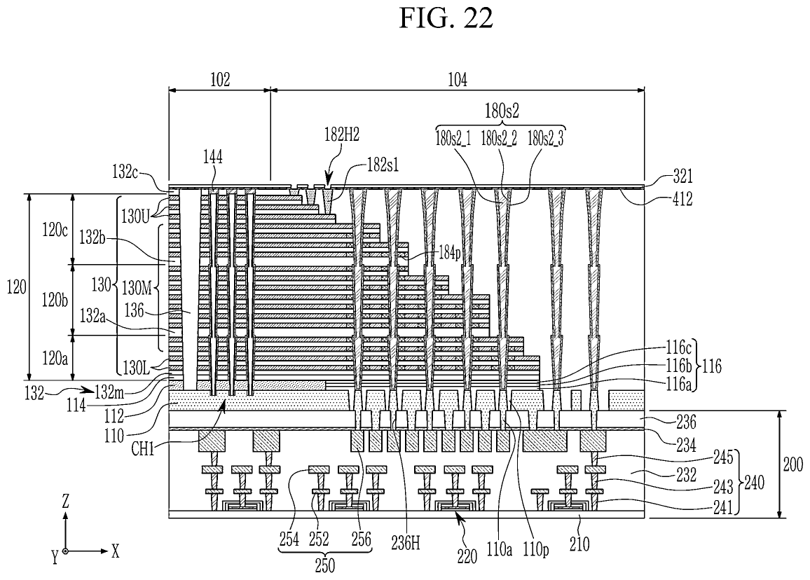

Subsequently, referring to FIG. 22, a planarization process may be performed such that the first channel pad 144 may be exposed. The planarization process step may be performed by, for example, chemical mechanical polishing (CMP). However, the planarization process method is not limited thereto, and may be changed in various ways.

In the planarization process step, a portion of the third upper gate insulation layer 132c, a portion of the separation structure 136, a portion of the gate contact portion sacrificial pattern 182s1 filling or in the first gate contact portion hole 182H1, a portion of the second contact portion sacrificial pattern 180s2 filling or in the first through-gate contact hole 184H1, the first source contact hole 186H1, and the first gate contact portion hole 182H1 may be removed together. By performing the planarization process, the upper surface of the third upper gate insulation layer 132c, the upper surface of the separation structure 136, an upper surface of the contact portion sacrificial pattern 182s1, and the upper surface of the second contact portion sacrificial pattern 180s2 may be substantially planarized.

Subsequently, the first upper insulation layer 412 and the second upper insulation layer 321 may be sequentially formed on the gate stacking structure 120.

The first upper insulation layer 412 may cover or overlap the first channel pad 144, the upper surface of the third upper gate insulation layer 132c, the upper surface of the separation structure 136, the first contact portion sacrificial pattern 180s1, and the upper surface of the second contact portion sacrificial pattern 180s2.

Subsequently, the second gate contact portion hole 182H2 that sequentially penetrates or extends into the second upper insulation layer 321 and the first upper insulation layer 412 and exposes the first contact portion sacrificial pattern 180s1 may be formed.

The first gate contact portion hole 182H1 according to the present embodiment may be a region where the second portions 182_1b, 182_2b, and 182_3b of the upper gate contact portion 182 according to an embodiment shown in FIG. 9 are formed.

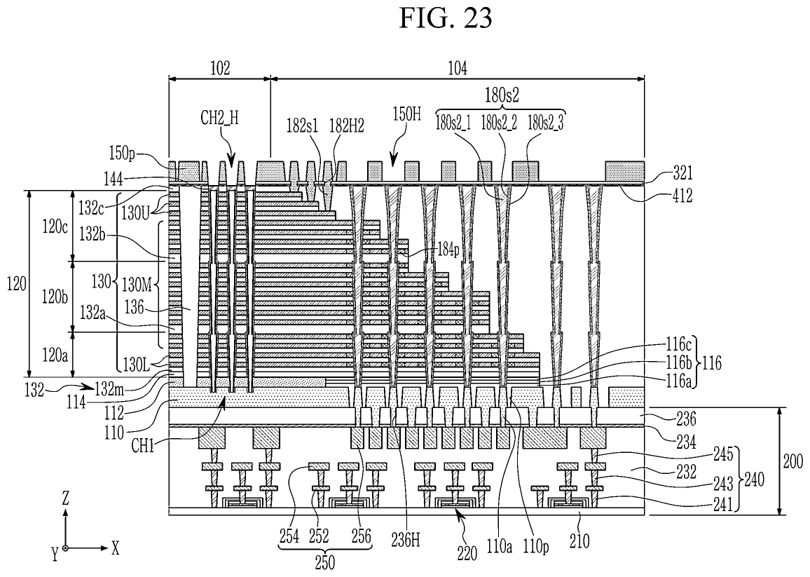

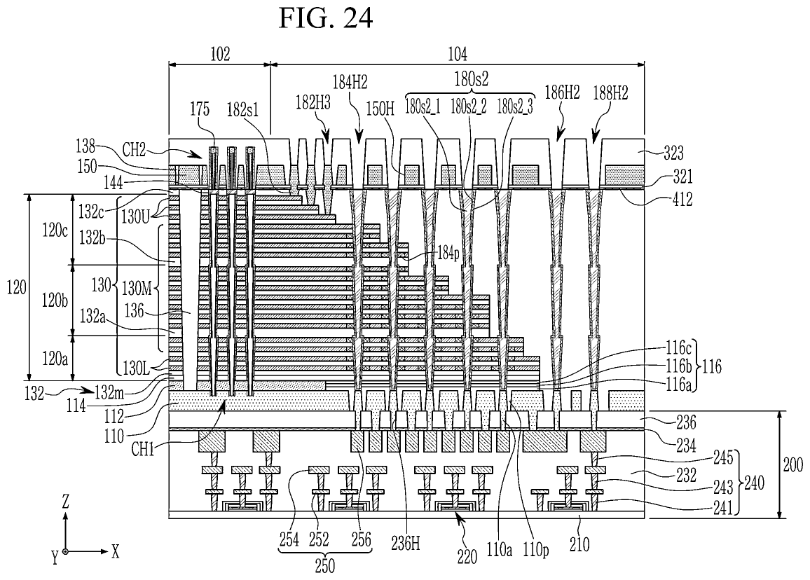

Subsequently, referring to FIG. 23, the selection gate material layer 150p for forming the selection gate electrode 150 (refer to FIG. 24) on the second upper insulation layer 321 may be formed. The selection gate material layer 150p may include, for example, polysilicon.

The selection gate material layer 150p may fill or be in the second gate contact portion hole 182H2.

Subsequently, by patterning the selection gate material layer 150p, the plurality of selection gate holes 150H penetrating or extending into the selection gate material layer 150p may be formed. The selection gate material layer 150p may be patterned, and the remaining selection gate material layer 150p may form the selection gate electrode 150 (refer to FIG. 24).

In the process of patterning the selection gate electrode 150, the second channel hole CH2_H may be formed in a region corresponding to the second channel structure CH2 positioned in the cell array region 102. The second channel hole CH2_H may sequentially penetrate or extend into the second upper insulation layer 321 and the first upper insulation layer 412, and expose the first channel pad 144. However, this is merely an example, and the second channel hole CH2_H may be formed by a separate process from the selection gate hole 150H.

Subsequently, and referring to FIG. 24, the third upper insulation layer 323 may be formed on the selection gate electrode 150. The third upper insulation layer 323 may fill or be in the second channel hole CH2_H and the selection gate hole 150H, and may cover or overlap the selection gate electrode 150.

Subsequently, by patterning the third upper insulation layer 323, a through-hole may be formed in a region corresponding to the second channel structure CH2. The through-hole may penetrate or extend into the third upper insulation layer 323 that fills or is in the second channel hole CH2_H, and expose the first channel pad 144.

Subsequently, the second channel structure CH2 is formed within the through-hole, an insulating material is formed in the selection gate hole 150H positioned in a region corresponding to the cell array region 102, and thereby, the upper separation structure 138 may be formed.

Subsequently, before forming a third gate contact portion hole 182H3, the second through-gate contact hole 184H2, the second source contact hole 186H2, and the second through-contact hole 188H2, the third upper insulation layer 323 that entirely covers or overlaps the second channel structure CH2 may be additionally formed. Accordingly, the third upper insulation layer 323 may cover or overlap the second channel pad 175.

Subsequently, in a region corresponding to the connecting region 104, the third gate contact portion hole 182H3, the second through-gate contact hole 184H2, the second source contact hole 186H2, and the second through-contact hole 188H2 may be formed by patterning the third upper insulation layer 323.

The third gate contact portion hole 182H3 may expose a portion of the selection gate electrode 150 connected to the selection gate material layer 150p that fills or is in the second gate contact portion hole 182H2 (refer to FIG. 23).

A portion of the selection gate electrode 150 positioned between the third gate contact portion hole 182H3 and the selection gate material layer 150p filling or in the second gate contact portion hole 182H2 may be a region where the third portions 182_1c, 182_2c, and 182_3c of the upper gate contact portion 182 according to an embodiment shown in FIG. 9 are formed, and the third gate contact portion hole 182H3 may be a region where the fourth portions 182_1d, 182_2d, and 182_3d of the upper gate contact portion 182 are formed.

Each the second through-gate contact hole 184H2, the second source contact hole 186H2, and the second through-contact hole 188H2 may sequentially penetrate or extend into the third upper insulation layer 323 filling or in the selection gate hole 150H, the second upper insulation layer 321, and the first upper insulation layer 412, and may expose the second contact portion sacrificial pattern 180s2.

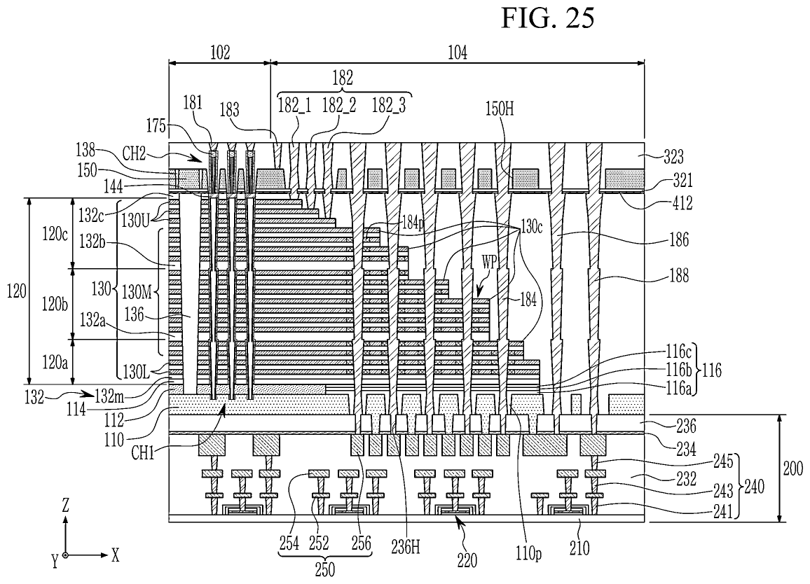

Subsequently, and referring to FIG. 25, a portion of the selection gate electrode 150 connected to the selection gate material layer 150p (refer to FIG. 24) filling or in the second gate contact portion hole 182H2 (refer to FIG. 23) through the third gate contact portion hole 182H3 may be removed. In the process step for removing a portion of the selection gate electrode 150, the gate contact portion sacrificial pattern 182s1 (refer to FIG. 23) in the first gate contact portion hole 182H1 (refer to FIG. 21) and the selection gate material layer 150p in the second gate contact portion hole 182H2 may be removed together, and accordingly, the upper gate electrode 130U may be sequentially exposed.

Subsequently, a conductive material such as tungsten (W), copper (Cu), aluminum (Al), or the like may be buried in the first gate contact portion hole 182H1, the second gate contact portion hole 182H2, a region from which a portion of the selection gate electrode 150 is removed, and the third gate contact portion hole 182H3 so as to be sequentially connected to the upper gate electrode 130U, and the upper gate contact portion 182 having the structure and shape shown in FIG. 9 may be formed.

According to a manufacturing method of a semiconductor device according to embodiments shown in FIG. 17 to FIG. 25, since a portion of the upper gate contact portion 182 connected to the upper gate electrode 130U is simultaneously formed in the process step for forming the contact portions 184, 186, and 188 that penetrate or extend into the gate stacking structure 120 and/or the cell insulation layer 132, and a remaining portion is simultaneously formed in the process step for forming the selection gate electrode 150, the process may be simplified compared to the case of performing a separate process in order to form the upper gate contact portion 182, and accordingly, productivity of the semiconductor device may be improved.

FIG. 26 is a drawing schematically showing an electronic system including a semiconductor device according to an embodiment.

As shown in FIG. 26, the electronic system 1000 according to an embodiment may include the semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid-state drive (SSD) device, a universal serial bus (USB), a computing system, a medical device, or communication device, which may include one or a plurality of semiconductor devices 1100.

The semiconductor device 1100 may be a non-volatile memory device, and may be, e.g., a NAND flash memory device described with reference to FIG. 1 to FIG. 10. The semiconductor device 1100 may include the first structure 1100F and the second structure 1100S on the first structure 1100F. In an embodiment, the first structure 1100F may be disposed next to the second structure 1100S. The first structure 1100F may be a peripheral circuit structure including the decoder circuit 1110, a page buffer 1120, and a logic circuit 1130. The second structure 1100S may be a memory cell structure including a bit line BL, a common source line CSL, a word line WL, first and second gate upper lines UL1 and UL2, and first and second gate lower lines LL1 and LL2, and the memory cell string CSTR between the bit line BL and the common source line CSL.

In the second structure 1100S, each of memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. A number of lower transistors LT1 and LT2 and a number of upper transistors UT1 and UT2 may be changed in various ways according to another embodiment.

In an embodiment, the lower transistors LT1 and LT2 may include a ground select transistor, and the upper transistors UT1 and UT2 may include a string select transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connecting wire 1115 extending from the first structure 1100F to the second structure 1100S. The bit line BL may be electrically connected to the page buffer 1120 through a second connecting wire 1125 extending to the second structure 1100S in the first structure 1100F.

In the first structure 1100F, the decoder circuit 1110 and the page buffer 1120 may execute a control operation on at least one memory cell transistor selected from among the memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connecting wire 1135 extending from the first structure 1100F to the second structure 1100S.

The controller 1200 may include a processor 1210, a NAND controller 1220, and a host interface 1230. Depending on embodiments, the electronic system 1000 may include the plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware, and may access the semiconductor devices 1100 by controlling the NAND controller 1220. The NAND controller 1220 may include a NAND interface 1221 that processes communication with the semiconductor devices 1100. A control command for controlling the semiconductor device 1100, data to be recorded in the memory cell transistor MCT of the semiconductor device 1100, and data to be read from the memory cell transistor MCT of the semiconductor device 1100 may be transmitted through the NAND interface 1221. The host interface 1230 may provide a communication function between the electronic system 1000 and an external host. When a control command is received from an external host through the host interface 1230, the processor 1210 may control the semiconductor devices 1100 in response to the control command.

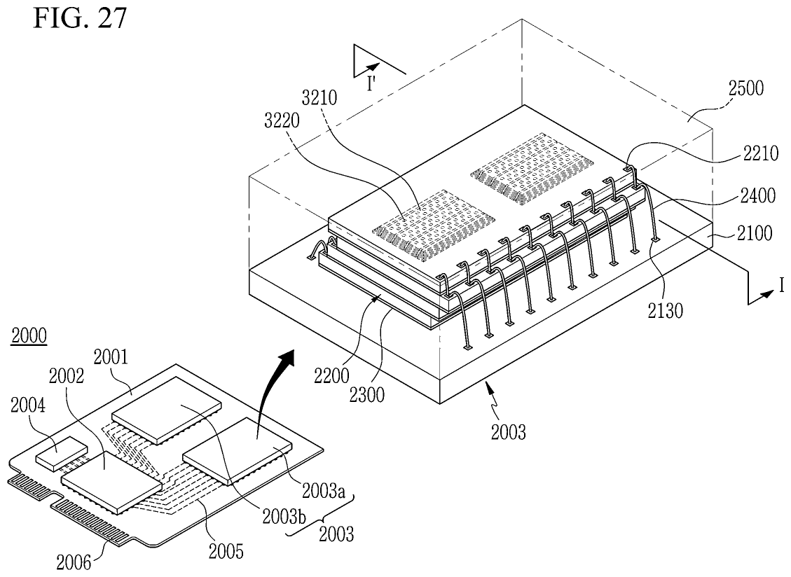

FIG. 27 a perspective view schematically showing an electronic system including a semiconductor device according to an embodiment.

As illustrated in FIG. 27, an electronic system 2000 according to an embodiment includes a main substrate 2001, a controller 2002 mounted on the main substrate 2001, one or more semiconductor packages 2003, and a DRAM 2004. The semiconductor package 2003 and the DRAM 2004 may be connected to the controller 2002 by a wiring pattern 2005 formed in the main substrate 2001.

The main substrate 2001 may include a connector 2006 including a plurality of pins coupled to an external host. The number and arrangement of pins in the connector 2006 may vary depending on a communication interface between the electronic system 2000 and the external host. In some embodiments, the electronic system 2000 may communicate with the external host according to any one of interfaces such as a universal flash storage (USB), a peripheral component interconnect express (PCI-Express), a serial advanced technology attachment (SATA), M-Phy for universal flash storage (UFS), and the like. In some embodiments, the electronic system 2000 may operate with power supplied from an external host through the connector 2006. The electronic system 2000 may further include a power management integrated circuit (PMIC) that distributes power supplied from the external host to the controller 2002 and semiconductor package 2003.

The controller 2002 may record data in the semiconductor package 2003, or may read data from the semiconductor package 2003, and may improve an operation speed of the electronic system 2000.

The DRAM 2004 may be a buffer memory for buffering a speed difference between the semiconductor package 2003, which is a data storage space, and an external host. The DRAM 2004 included in the electronic system 2000 may also operate as a kind of cache memory, and may provide a space for temporarily storing data in the control operation for the semiconductor package 2003. When the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. The first and second semiconductor packages 2003a and 2003b may be semiconductor packages each including a plurality of semiconductor chips 2200. Each of the first and second semiconductor packages 2003a and 2003b may include a package substrate 2100, a semiconductor chip 2200 on the package substrate 2100, an adhesive layer 2300 disposed on a lower surface of each semiconductor chip 2200, a connecting structure 2400 that electrically connects the semiconductor chip 2200 and the package substrate 2100, and a molding layer 2500 covering the semiconductor chip 2200 and the connection structure 2400 on the package substrate 2100.

The package substrate 2100 may be a printed circuit board including a package upper pad 2130. Each the semiconductor chip 2200 may include an input/output pad 2210. The input/output pad 2210 may correspond to the input/output pad 1101 of FIG. 26. Each of the semiconductor chip 2200 may include a gate stacking structure 3210 and a channel structure 3220. The semiconductor chip 2200 may include the semiconductor device described with reference to FIG. 1 to FIG. 10.

In some embodiments, the connecting structure 2400 may be a bonding wire electrically connecting the input/output pad 2210 and the package upper pad 2130. Accordingly, the semiconductor chips 2200 may be electrically connected to each other by using a bonded wire method, and may be electrically connected to the package upper pad 2130 of the package substrate 2100 in each of the first and second semiconductor packages 2003a and 2003b. According to an embodiment, the semiconductor chips 2200 may be electrically connected to each other by a connecting structure including a through silicon via (TSV) instead of the bonding wire connecting structure 2400 in each of the first and second semiconductor packages 2003a and 2003b.

In an embodiment, the controller 2002 and the semiconductor chip 2200 may be included to one package. For example, the controller 2002 and the semiconductor chip 2200 may be mounted on a separate interposer substrate that is different from the main substrate 2001, and the controller 2002 and the semiconductor chip 2200 may be connected to each other by a wire positioned on the interposer substrate.

FIG. 28 and FIG. 29 are cross-sectional views schematically showing a semiconductor package according to an embodiment. FIG. 28 and FIG. 29 each illustrate an embodiment of the semiconductor package 2003 of FIG. 27, and conceptually illustrates an area of the semiconductor package 2003 of FIG. 27 taken along a line I-I′.

Referring to FIG. 28, in the semiconductor package 2003, the package substrate 2100 may be a printed circuit board. The package substrate 2100 may include a package substrate body 2120, the package upper pad 2130 positioned on an upper surface of the package substrate body 2120, a lower pad 2125 positioned on a surface of the package substrate body 2120, and an inner wire 2135 that electrically connects the upper pad 2130 and the lower pad 2125 inside the package substrate body 2120. The upper pad 2130 may be electrically connected to the connection structure 2400. The lower pad 2125 may be connected to the wire pattern 2005 of the main substrate 2001 of the electronic system 2000 through a conductive connector 2800 as illustrated in FIG. 23.

The semiconductor chip 2200 may include a semiconductor substrate 3010, and the first structure 3100 and the second structure 3200 sequentially stacked on the semiconductor substrate 3010. The first structure 3100 may include a peripheral circuit region including a peripheral wire 3110. The second structure 3200 may include a common source line 3205, a gate stack structure 3210 on the common source line 3205, a channel structure 3220 and a separating structure 3230 through the gate stack structure 3210, a bit line 3240 electrically connected to the channel structure 3220, and a gate connecting wire electrically connected to a word line WL (refer to FIG. 26) of the gate stack structure 3210.

In the semiconductor chip 2200 or a semiconductor device according to an embodiment, since the gate stacking structure 120 and the upper gate contact portion 182 connected to the upper gate electrode 130U and/or contact portions 184, 184, 186, and 188 that penetrate or extend into the cell insulation layer 132 are formed by the same process step, the process may be simplified compared to the case of performing a separate process in order to form the upper gate contact portion 182, and accordingly, productivity of the semiconductor device may be improved.

In addition, since the upper gate contact portion 182 and the contact portions 184, 184, 186, and 188 are formed by the same process step, the distribution of the upper gate contact portion 182 and the contact portions 184, 184, 186, and 188 may be improved, such that the upper gate contact portion 182 and the contact portions 184, 184, 186, and 188 may be stably formed, and accordingly, a semiconductor device having improved reliability may be provided.

Each of the semiconductor chips 2200 may include a through wire 3245 that is electrically connected to the peripheral wire 3110 of the first structure 3100 and extends into the second structure 3200. The through wire 3245 may extend through the gate stack structure 3210, and may be further positioned outside the gate stack structure 3210. Each semiconductor chip 2200 may further include an input/output connection wire 3265 electrically connected to the peripheral wire 3110 of the first structure 3100 and the input/output pad 2210 electrically connected to the input/output connecting wire 3265 extending into the second structure 3200.

In an embodiment, a plurality of semiconductor chips 2200 in the semiconductor package 2003 may be electrically connected to each other by a connecting structure 2400 having a form of a bonding wire. As another example, the semiconductor chips 2200 or a plurality of portions constituting the semiconductor chips 2200 may be electrically connected by a connecting structure including a through silicon via (TSV).

Referring to FIG. 29, in a semiconductor package 2003A, each semiconductor chip 2200 may include a semiconductor substrate 4010, a first structure 4100 on the semiconductor substrate 4010, and a second structure 4200 bonded to a first structure 4100 by wafer bonding on the first structure 4100.

The first structure 4100 may include a peripheral circuit region including a peripheral wire 4110 and a first junction structure 4150. The second structure 4200 may include a common source line 4205, a gate stack structure 4210 between the common source line 4205 and the first structure 4100, a channel structure 4220 and a separating structure 4230 extending through the gate stack structure 4210, and a second junction structure 4250 electrically connected to the word line WL (refer to FIG. 26, hereinafter the same) of each of the channel structure 4220 and the gate stack structure 4210. For example, the second junction structure 4250 may be electrically connected to the channel structure 4220 and the word line WL through a bit line 4240 electrically connected to the channel structure 4220 and a gate connecting wire electrically connected to the word line WL, respectively. The first junction structure 4150 of the first structure 4100 and the second junction structure 4250 of the second structure 4200 may be bonded while contacting each other. The bonded portion of the first bonding structure 4150 and the second bonding structure 4250 may be formed of, for example, copper (Cu).

In the semiconductor chip 2200 or a semiconductor device according to an embodiment, since the gate stacking structure 120 and the upper gate contact portion 182 connected to the upper gate electrode 130U and/or the contact portions 184, 184, 186, and 188 that penetrate or extend into the cell insulation layer 132 are formed by the same process step, the process may be simplified compared to the case of performing a separate process in order to form the upper gate contact portion 182, and accordingly, productivity of the semiconductor device may be improved.

In addition, since the upper gate contact portion 182 and the contact portions 184, 184, 186, and 188 are formed by the same process step, the distribution of the upper gate contact portion 182 and the contact portions 184, 184, 186, and 188 may be improved, such that the upper gate contact portion 182 and the contact portions 184, 184, 186, and 188 may be stably formed, and accordingly, a semiconductor device having improved reliability may be provided.

Each of the semiconductor chip 2200 may further include the input/output pad 2210 and an input/output connection wiring 4265 below the input/output pad 2210. The input/output connection wiring 4265 may be electrically connected to a portion of the second bonding structure 4250.

In an embodiment, a plurality of semiconductor chips 2200 in the semiconductor package 2003 may be electrically connected to each other by a connecting structure 2400 having a form of a bonding wire. As another example, the semiconductor chips 2200 or a plurality of portions constituting the semiconductor chips 2200 may be electrically connected by a connecting structure including the through silicon via (TSV).

While this disclosure has been described in connection with what is presently considered to be practical embodiments, it is to be understood that the disclosure is not limited to the disclosed embodiments, but, on the contrary, is intended to cover various modifications and equivalent dispositions included within the spirit and scope of the appended claims.

What is claimed is:

1. A semiconductor device, comprising:
a substrate comprising a circuit region and a cell region;
wherein the circuit region comprises a peripheral circuit structure on the substrate;
wherein the cell region is on the circuit region and comprises a cell array region and a connecting region, and
wherein the cell region comprises:
a gate stacking structure comprising a plurality of interlayer insulation layers and a plurality of gate electrodes that are alternately stacked on the substrate;
a channel structure that extends into the gate stacking structure and is on the cell array region;
a through-gate contact portion that extends into the gate stacking structure and is on the connecting region, wherein the through-gate contact portion is electrically connected to a connection gate electrode among the plurality of gate electrodes, wherein the plurality of gate electrodes extend into an insulation pattern; and
an upper gate contact portion that is electrically connected to an upper gate electrode among the plurality of gate electrodes, wherein the upper gate electrode is separated from the substrate by a first distance in a vertical direction that is perpendicular to the substrate, wherein the connection gate electrode is separated from the substrate by a second distance in the vertical direction, and wherein the second distance is less than the first distance,
wherein the upper gate contact portion comprises a first portion and a second portion, and
wherein a boundary between the first portion and the second portion has a step shape.

2. The semiconductor device of claim 1, wherein a width of an upper surface of the first portion of the upper gate contact portion and a width of a bottom surface of the second portion of the upper gate contact portion are different.

3. The semiconductor device of claim 2, wherein a length of the first portion of the upper gate contact portion in the vertical direction is different from a length of the second portion of the upper gate contact portion in the vertical direction.

4. The semiconductor device of claim 3, wherein:
a width of a bottom surface of the first portion of the upper gate contact portion is less than the width of the upper surface of the first portion of the upper gate contact portion; and
the width of the bottom surface of the second portion of the upper gate contact portion is less than a width of the upper surface of the second portion of the upper gate contact portion.

5. The semiconductor device of claim 2, wherein:
the upper gate contact portion further comprises a third portion on the second portion of the upper gate contact portion; and
a width of an upper surface of the second portion of the upper gate contact portion is less than or equal to a width of a bottom surface of the third portion of the upper gate contact portion.

6. The semiconductor device of claim 5, wherein:
a width of the bottom surface of the second portion of the upper gate contact portion is less than the width of the upper surface of the second portion of the upper gate contact portion; and
the width of the bottom surface of the third portion of the upper gate contact portion is greater than a width of an upper surface of the third portion of the upper gate contact portion.

7. The semiconductor device of claim 6, wherein:
the upper gate contact portion further comprises a fourth portion between the upper gate electrode and the first portion of the upper gate contact portion; and
the fourth portion of the upper gate contact portion has a second step shape.

8. The semiconductor device of claim 7, wherein:
a width of a bottom surface of the fourth portion of the upper gate contact portion is greater than a width of a bottom surface of the fourth portion of the upper gate contact portion;
a width of a bottom surface of the first portion of the upper gate contact portion is less than a width of the upper surface of the fourth portion of the upper gate contact portion; and
the width of the upper surface of the first portion of the upper gate contact portion is less than the width of the bottom surface of the second portion of the upper gate contact portion.

9. The semiconductor device of claim 1, wherein the through-gate contact portion comprises:
a first portion that is separated from the substrate by a third distance in the vertical direction, wherein a bottom surface of the upper gate contact portion is separated from the substrate by a fourth distance in the vertical direction, and wherein the fourth distance is greater than the third distance; and
a second portion that is on the first portion of the through-gate contact portion, wherein the first portion of the upper gate contact portion and the second portion of the through-gate contact portion are separated from the substrate by a fifth distance in the vertical direction,
wherein an inclination of a side surface of the first portion of the through-gate contact portion and an inclination of a side surface of the second portion of the through-gate contact portion are different.

10. The semiconductor device of claim 1, wherein the upper gate contact portion is between the channel structure and the through-gate contact portion.

11. The semiconductor device of claim 10, wherein:
the gate stacking structure comprises a plurality of upper gate electrodes comprising the upper gate electrode, wherein the plurality of upper gate electrodes comprise different lengths in a horizontal direction that is parallel to the substrate and are stacked on each other,
the semiconductor device further comprises a plurality of upper gate contact portions comprising the upper gate contact portion, wherein the plurality of upper gate contact portions are respectively electrically connected to ones of the plurality of upper gate electrodes, and
lengths of respective first portions of the plurality of upper gate contact portions in the vertical direction are different, and
lengths of respective second portions of a plurality of upper gate contact portions in the vertical direction are substantially equal.

12. A semiconductor device, comprising:
a substrate comprising a circuit region and a cell region;
wherein the circuit region comprises a peripheral circuit structure on the substrate;
wherein the cell region is on the circuit region,
wherein the cell region comprises:
a gate stacking structure comprising a plurality of interlayer insulation layers and a plurality of gate electrodes that are alternately stacked on the substrate;
a first channel structure that extends into the gate stacking structure;
a selection gate electrode on the gate stacking structure;
a second channel structure that extends into the selection gate electrode and is electrically connected to the first channel structure;
a through-gate contact portion that extends into the selection gate electrode and the gate stacking structure and is electrically connected to a connection gate electrode among the plurality of gate electrodes, wherein the plurality of gate electrodes extend into an insulation pattern; and
an upper gate contact portion that extends into the selection gate electrode and is electrically connected to an upper gate electrode among the plurality of gate electrodes, wherein the upper gate electrode is separated from the substrate by a first distance in a vertical direction that is perpendicular to the substrate, wherein the connection gate electrode is separated from the substrate by a second distance in the vertical direction, and wherein the second distance is less than the first distance,
wherein the upper gate contact portion comprises:
a first portion that is separated from the substrate by a third distance in the vertical direction, wherein the selection gate electrode is separated from the substrate by a fourth distance in the vertical direction, and wherein the third distance is less than the fourth distance; and
a second portion that extends into the selection gate electrode and is on the first portion, and
wherein a width of an upper surface of the first portion of the upper gate contact portion and a width of a bottom surface of the second portion of the upper gate contact portion are different.

13. The semiconductor device of claim 12, wherein a length of the first portion of the upper gate contact portion in the vertical direction is less than a length of the second portion of the upper gate contact portion in the vertical direction.

14. The semiconductor device of claim 13, wherein:
the upper gate contact portion further comprises a third portion on the second portion of the upper gate contact portion,
a bottom surface of the selection gate electrode and a boundary of the first portion and the second portion of the upper gate contact portion are separated from the substrate by a fifth distance, and
an upper surface of the selection gate electrode and a boundary of the second portion and the third portion of the upper gate contact portion are separated from the substrate by a sixth distance.

15. The semiconductor device of claim 14, wherein:
a width of an upper surface of the second portion of the upper gate contact portion is greater than or substantially equal to a width of a bottom surface of the third portion of the upper gate contact portion;
a width of a bottom surface of the second portion of the upper gate contact portion is less than the width of the upper surface of the second portion of the upper gate contact portion; and
a width of a bottom surface of the third portion of the upper gate contact portion is greater than a width of an upper surface of the third portion of the upper gate contact portion.

16. The semiconductor device of claim 14, wherein:
the upper gate contact portion further comprises a fourth portion between the first portion of the upper gate contact portion and the upper gate electrode, and
wherein a width of a bottom surface of the first portion of the upper gate contact portion and a width of a bottom surface of the fourth portion of the upper gate contact portion are different.

17. The semiconductor device of claim 16, wherein the length of the first portion of the upper gate contact portion in the vertical direction is less than a length of the third portion of the upper gate contact portion in the vertical direction.

18. The semiconductor device of claim 17, wherein:
a length of the fourth portion of the upper gate contact portion in the vertical direction is greater than the length of the first portion of the upper gate contact portion in the vertical direction; and
the length of the fourth portion of the upper gate contact portion in the vertical direction is different from the length of the second portion of the upper gate contact portion in the vertical direction and the length of the third portion of the upper gate contact portion in the vertical direction.

19. The semiconductor device of claim 12, further comprising:
the gate stacking structure comprises a plurality of upper gate electrodes that comprise the upper gate electrode, wherein one of the plurality of upper gate electrodes have different respective lengths in a horizontal direction and are stacked on each other; and
the upper gate contact portion further comprises a dummy gate electrode comprising a plurality of upper gate contact portions that are respectively and electrically connected to respective ones of the plurality of upper gate electrodes, respectively, wherein the plurality of upper gate contact portions are between second portions of adjacent ones among the plurality of upper gate contact portions.

20. An electronic system, comprising:
a main substrate;
a semiconductor device on the main substrate; and
a controller that is electrically connected to the semiconductor device and is on the main substrate,
wherein the semiconductor device comprises a circuit region comprising a peripheral circuit structure on a substrate and a cell region on the circuit region,
wherein the cell region comprises:
a gate stacking structure comprising a plurality of interlayer insulation layers and a plurality of gate electrodes that are alternately stacked on the substrate;
a first channel structure that extends into the gate stacking structure;
a selection gate electrode on the gate stacking structure;
a second channel structure that extends into the selection gate electrode and is electrically connected to the first channel structure;
a through-gate contact portion that extends into the selection gate electrode and the gate stacking structure, is electrically connected to a connection gate electrode among the plurality of gate electrodes that extend into an insulation pattern, and is insulated from one or more second gate electrodes among the plurality of gate electrodes; and
an upper gate contact portion that extends into the selection gate electrode and is electrically connected to an upper gate electrode among the plurality of gate electrodes, wherein the upper gate electrode is separated from the substrate by a first distance in a vertical direction that is perpendicular to the substrate, wherein the connection gate electrode is separated from the substrate by a second distance in the vertical direction, and wherein the second distance is less than the first distance,
wherein the upper gate contact portion comprises:
a first portion that is separated from the substrate by a third distance in the vertical direction, wherein the selection gate electrode is separated from the substrate by a fourth distance in the vertical direction, and wherein the third distance is less than the fourth distance; and
a second portion that extends into the selection gate electrode and is on the first portion,
wherein a width of an upper surface of the first portion of the upper gate contact portion and a width of a bottom surface of the second portion of the upper gate contact portion are different, and
wherein a length of the first portion of the upper gate contact portion in the vertical direction is different from a length of the second portion of the upper gate contact portion in the vertical direction.
